(19) United States
(12) Patent Application Publication
(10) Pub. No.: US 2024/0297045 A1
(43) Pub. Date: Sep. 5, 2024

(54) METHOD OF MANUFACTURING SEMICONDUCTOR DEVICE

(71) Applicant: Kioxia Corporation, Tokyo (JP)

(72) Inventors: Yoshio MIZUTA, Yokkaichi (JP); Sadatoshi MURAKAMI, Yokkaichi (JP)

(73) Assignee: Kioxia Corporation, Tokyo (JP)

(21) Appl. No.: 18/591,438

(22) Filed: Feb. 29, 2024

(30) Foreign Application Priority Data
Mar. 2, 2023 (JP) 2023-031776

(51) Int. Cl. H01L 21/268; H01L 21/683; H01L 21/762; H01L 21/78; H01L 23/00; H01L 25/065; H10B 80/00

(52) U.S. Cl. CPC H01L 21/268; H01L 21/6835; H01L 21/76251; H01L 21/7813; H01L 24/80; H01L 25/0657; H10B 80/00; H01L 2221/68386; H01L 2224/80006; H01L 2224/80948; H01L 2924/10158; H01L 2924/4015

(57) ABSTRACT

According to one embodiment, there is provided a method of manufacturing a semiconductor device. The method includes preparing a first substrate on which multiple projections distributed in a two-dimensional fashion are formed. The method includes stacking a first film over the multiple projections on the first substrate. The method includes stacking a second film on a second substrate. The method includes bonding a principal surface of the first film which is disposed on an opposite side of the first substrate to a principal surface of the second film which is disposed on an opposite side of the second substrate. The method includes performing irradiation with a laser beam from the first substrate. The method includes peeling the first substrate. A diameter of a spot area formed by the laser beam is larger than an average pitch between the projections arranged on the principal surface of the first substrate.

### CROSS-REFERENCE TO RELATED APPLICATIONS

This application is based upon and claims the benefit of Japanese Patent Application No. 2023-031776, filed on Mar. 2, 2023; the entire contents of which are incorporated herein by reference.

### FIELD

Embodiments described herein relate generally to a method of manufacturing a semiconductor device.

### BACKGROUND

When a semiconductor device is manufactured, there are cases where two substrates are bonded together, and then one of the two substrates is peeled by irradiation with a laser beam (laser peel). This laser peel needs to have an improved throughput.

### BRIEF DESCRIPTION OF THE DRAWINGS

FIG. 1 is a flowchart illustrating a method of manufacturing a semiconductor device according to a first embodiment;

FIGS. 2A to 2F are cross-sectional views illustrating the method of manufacturing the semiconductor device according to the first embodiment;

FIGS. 3A and 3B are enlarged cross-sectional views illustrating the method of manufacturing the semiconductor device according to the first embodiment;

FIG. 4 is a plan view illustrating the method of manufacturing the semiconductor device according to the first embodiment;

FIGS. 5A and 5B are cross-sectional views illustrating the method of manufacturing the semiconductor device according to the first embodiment;

FIG. 6 is an enlarged cross-sectional view illustrating the method of manufacturing the semiconductor device according to the first embodiment;

FIG. 7 is a plan view illustrating the method of manufacturing the semiconductor device according to the first embodiment;

FIGS. 8A to 8C are cross-sectional views illustrating the method of manufacturing the semiconductor device according to the first embodiment;

FIGS. 9A to 9D are cross-sectional views illustrating the method of manufacturing the semiconductor device according to the first embodiment;

FIGS. 10A to 10C are cross-sectional views illustrating the method of manufacturing the semiconductor device according to the first embodiment;

FIG. 11 is a cross-sectional view illustrating generation of stress in the first embodiment;

FIGS. 12A to 12E are cross-sectional views illustrating the method of manufacturing the semiconductor device according to the first embodiment;

FIG. 13 is an enlarged cross-sectional view illustrating the method of manufacturing the semiconductor device according to the first embodiment;

FIG. 14 is a plan view illustrating a method of manufacturing a semiconductor device according to a first modification of the first embodiment;

FIGS. 15A to 15F are cross-sectional views illustrating a method of manufacturing a semiconductor device according to a second modification of the first embodiment;

FIGS. 16A to 16G are cross-sectional views illustrating a method of manufacturing a semiconductor device according to a third modification of the first embodiment;

FIG. 17 is a flowchart illustrating a method of manufacturing a semiconductor device according to a second embodiment;

FIGS. 18A to 18E are cross-sectional views illustrating the method of manufacturing the semiconductor device according to the second embodiment;

FIGS. 19A and 19B are cross-sectional views illustrating the method of manufacturing the semiconductor device according to the second embodiment;

FIGS. 20A to 20C are plan views each illustrating a multi-segment irradiation pattern according to the second embodiment;

FIGS. 21A to 21D are cross-sectional views illustrating the method of manufacturing the semiconductor device according to the second embodiment;

FIG. 22 is a cross-sectional view illustrating the method of manufacturing the semiconductor device according to the second embodiment;

FIGS. 23A to 23C are plan views each illustrating a multi-segment irradiation pattern according to a first modification of the second embodiment;

FIGS. 24A to 24C are plan views each illustrating a multi-segment irradiation pattern according to a second modification of the second embodiment;

FIG. 25 is a plan view illustrating generation of stress in the second modification of the second embodiment;

FIGS. 26A to 26C are plan views each illustrating a multi-segment irradiation pattern according to a third modification of the second embodiment; and

FIG. 27 is a plan view illustrating generation of stress in the third modification of the second embodiment.

### DETAILED DESCRIPTION

In general, according to one embodiment, there is provided a method of manufacturing a semiconductor device. The method includes preparing a first substrate on which multiple projections distributed in a two-dimensional fashion are formed. The method includes stacking a first film over the multiple projections on the first substrate. The method includes stacking a second film on a second substrate. The method includes bonding a principal surface of the first film which is disposed on an opposite side of the first substrate to a principal surface of the second film which is disposed on an opposite side of the second substrate. The method includes performing irradiation with a laser beam from the first substrate. The method includes peeling the first substrate. A diameter of a spot area formed by the laser beam is larger than an average pitch between the projections arranged on the principal surface of the first substrate.

Exemplary embodiments of a method of manufacturing a semiconductor device will be explained below in detail with reference to the accompanying drawings. The present invention is not limited to the following embodiments.

### First Embodiment

In a method of manufacturing a semiconductor device according to a first embodiment, two substrates are bonded together, and then one of the two substrates is peeled from the other (laser peel) by irradiation with a laser beam. Various improvements are made to perform this laser peel efficiently.

Hereinafter, of the two substrates bonded together, the other substrate to be left without being peeled is defined as a reference substrate. A direction vertical to the principal surface of the other substrate is defined as a Z direction, whereas two directions orthogonal to each other in a plane vertical to the Z direction are defined as an X direction and a Y direction.

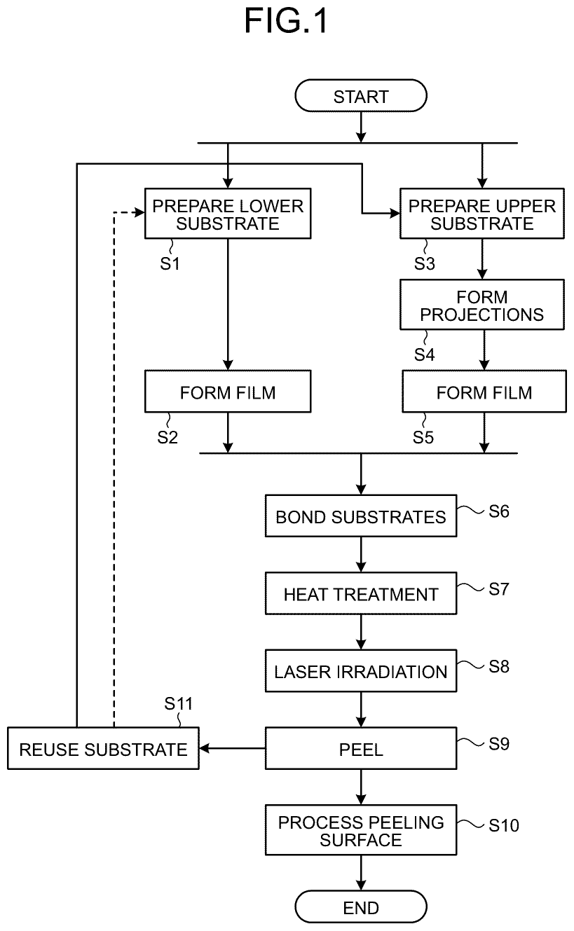

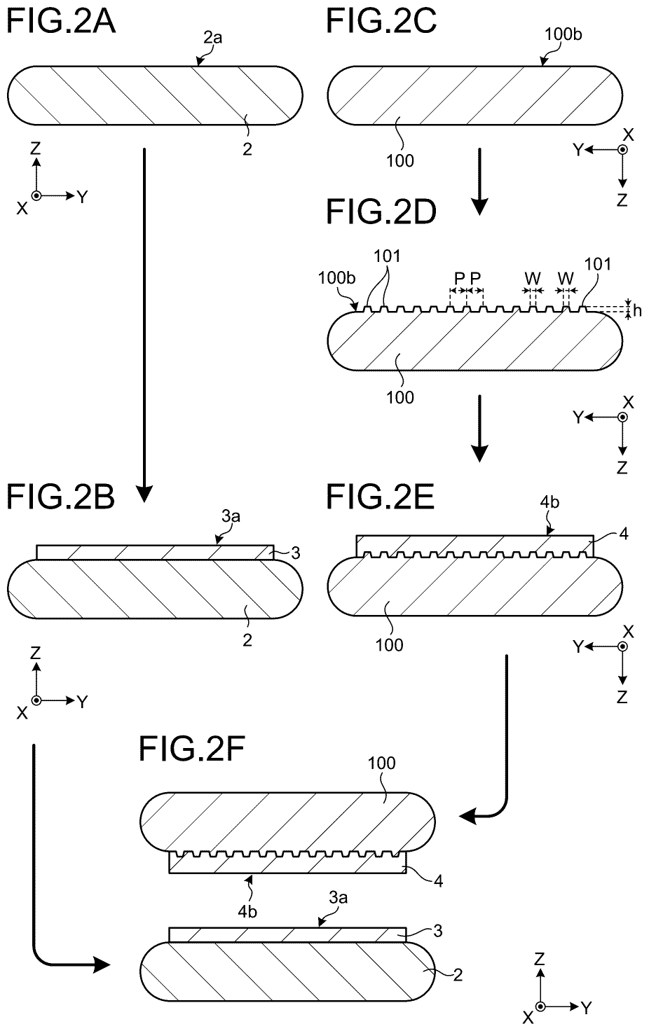

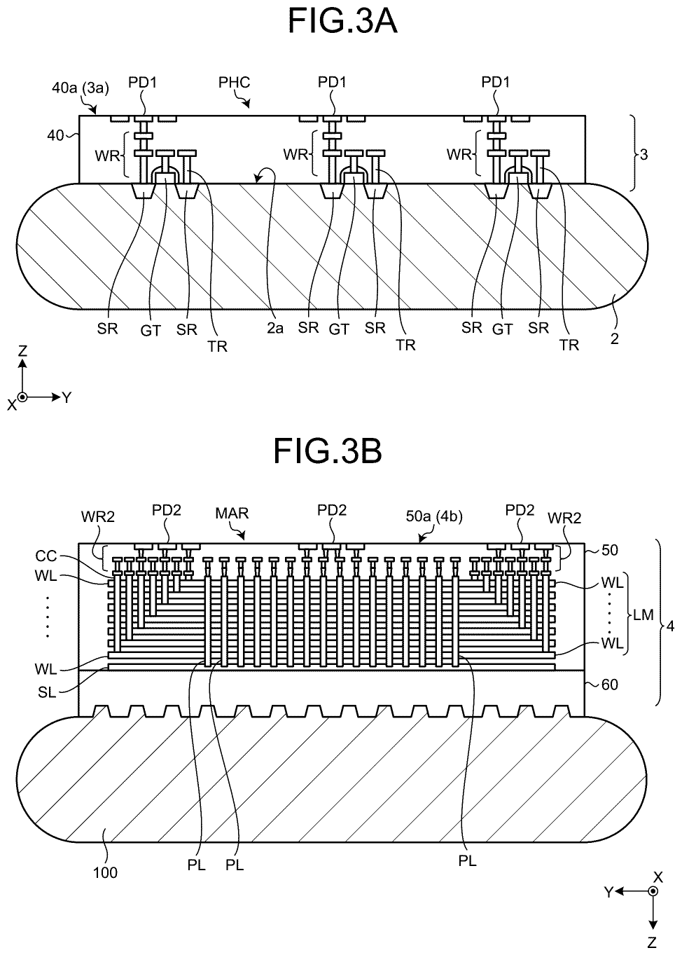

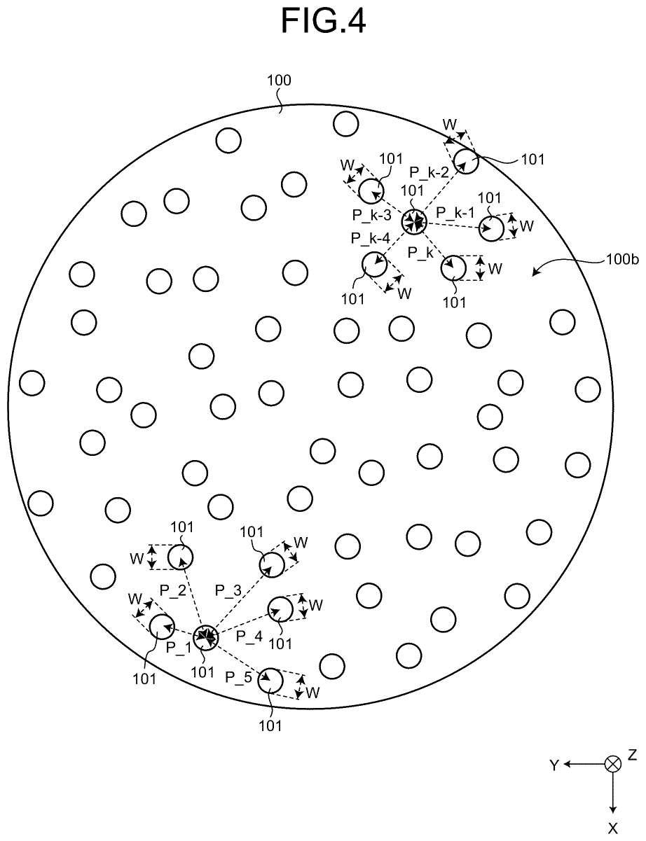

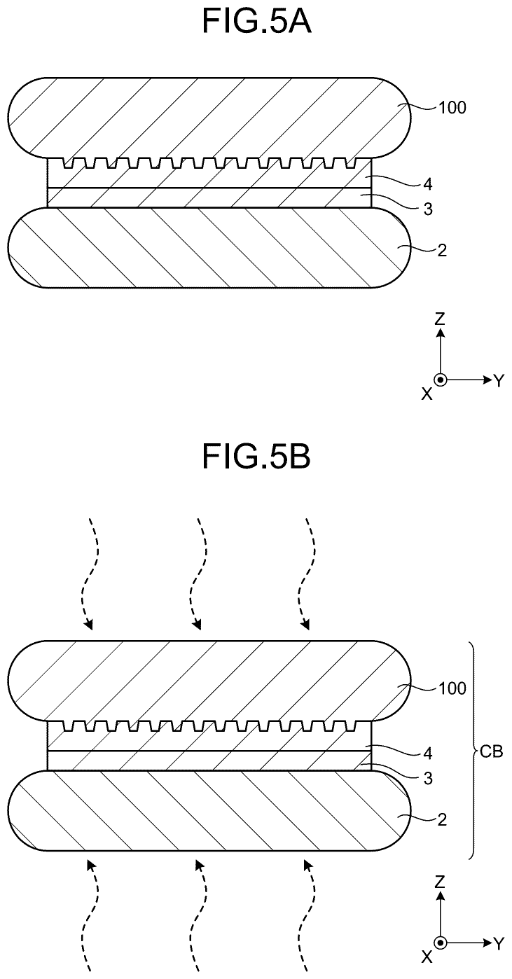

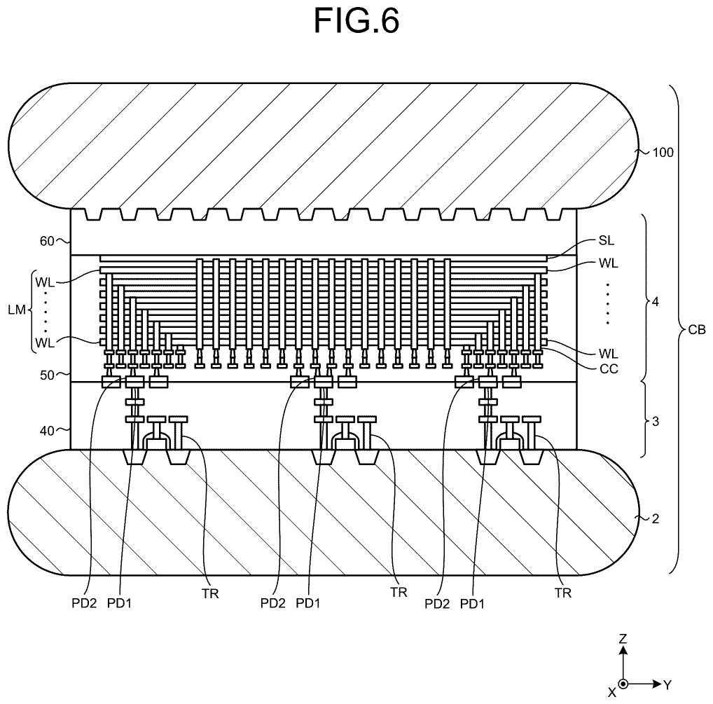

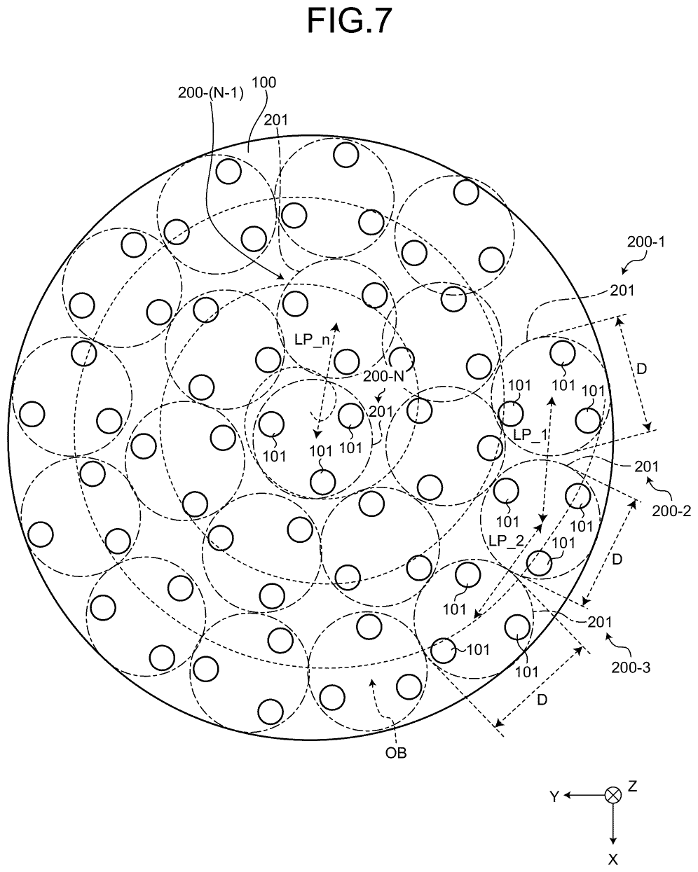

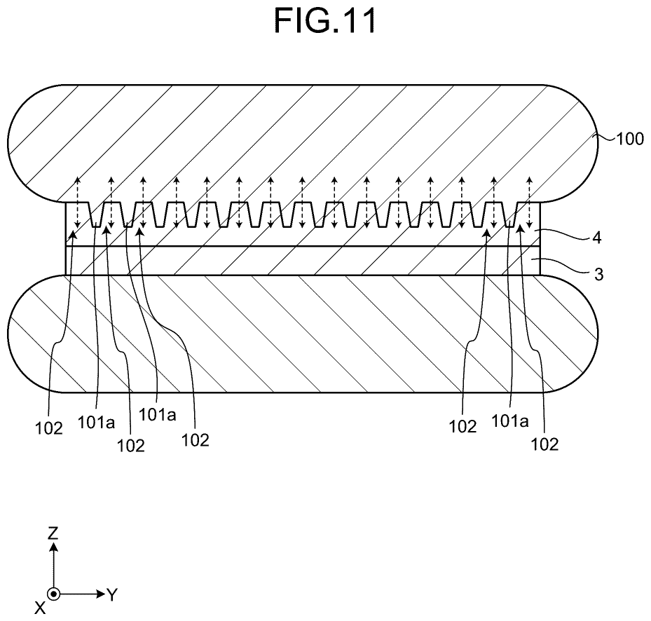

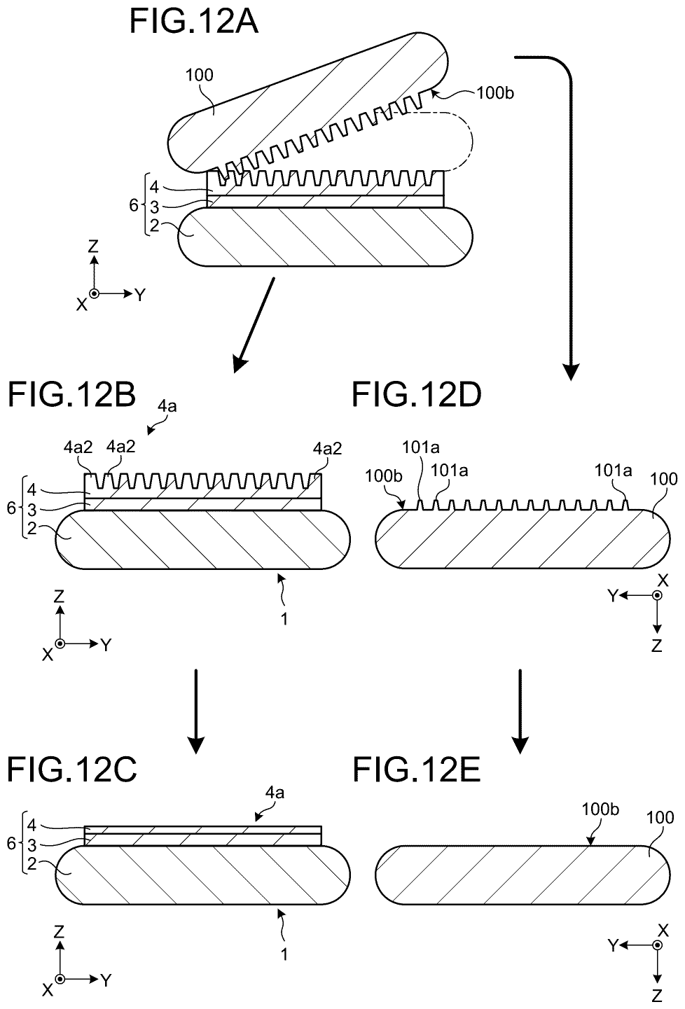

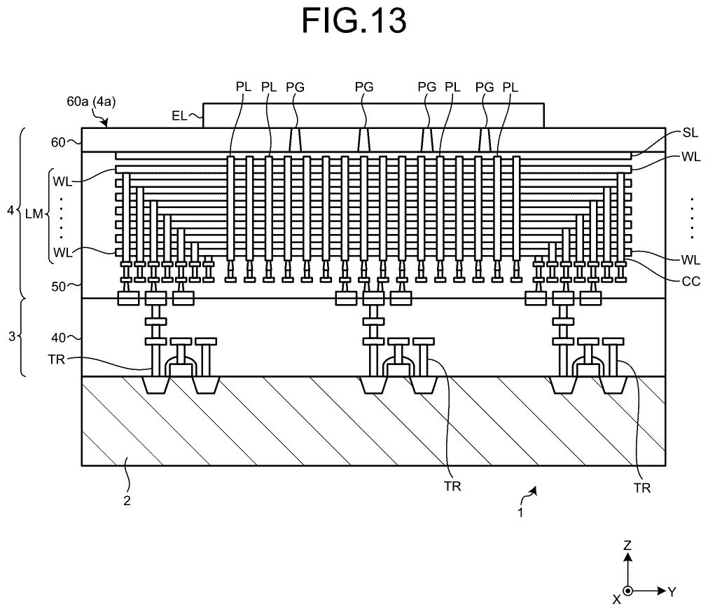

For example, a method of manufacturing a semiconductor device 1 can be performed, as illustrated in FIGS. 1 to 13. FIG. 1 is a flowchart illustrating the method of manufacturing the semiconductor device 1. FIGS. 2A to 2F, 3A, 3B, 5A, 5B, 6, 8A to 8C, 9A to 9C, 10A to 10C, 12A to 12E, and 13 are each a Y-Z cross-sectional view illustrating the method of manufacturing the semiconductor device 1. FIG. 3A is an enlarged cross-sectional view of FIG. 2A. FIG. 3B is an enlarged cross-sectional view of FIG. 2E. FIG. 6 is an enlarged cross-sectional view of FIG. 5A. FIG. 13 is an enlarged cross-sectional view of FIG. 12E. FIG. 11 is a Y-Z cross-sectional view illustrating generation of stress. FIGS. 4 and 7 are X-Y plan views illustrating the method of manufacturing the semiconductor device 1.

In the method of manufacturing the semiconductor device 1, as illustrated in FIG. 1, a process on a lower substrate (S1 and S2) and a process on an upper substrate (S3 to S5) are performed, for example, in parallel with each other. The lower substrate corresponds to one of the two substrates to be placed together which is disposed on the −Z side upon the bonding. The upper substrate corresponds to one of the two substrates to be bonded together which is placed on the +Z side upon the bonding.

In preparing of the lower substrate (S1), a substrate (lower substrate) 2 is prepared, as illustrated in FIG. 2A. The substrate 2 may be made of, as its main material, a semiconductor material (e.g., silicon) that does not substantially contain impurities.

In forming of a film (S2), as illustrated in FIG. 2B, a predetermined device structure is formed on a principal surface 2a of the substrate 2 which is disposed on the +Z side.

For example, a peripheral circuit structure PHC may be formed, as illustrated in FIG. 3A. Impurities are introduced into a portion of the substrate 2 near the principal surface 2a disposed on the +Z side, so that semiconductor regions SR are formed. Conductive patterns GT are then formed on the principal surface 2a of the substrate 2. As a result, multiple transistors TR each of which includes the semiconductor region SR and the conductive pattern GT are formed. The peripheral circuit structure PHC, which includes the multiple transistors TR, functions as a peripheral circuit for a memory cell array structure MAR that will be described later.

After the predetermined device structure has been formed, a film 3 is formed with a chemical vapor deposition (CVD) method or any other suitable method. For example, an interlayer insulating film 40 may be made of a material containing an insulating component as its main component or may be made of a material containing a semiconductor oxide (e.g., silicon oxide) as its main component. In addition to depositing the interlayer insulating film 40, holes are formed inside the interlayer insulating film 40. Then, a conductive material is embedded into and conductive patterns are formed inside the holes. In this way, wiring structures WR that are electrically connected to the transistors TR are formed. Electrodes PD1 that are electrically connected to the wiring structures WR are formed with plating, for example, on a principal surface 40a of the interlayer insulating film 40 which is disposed on the +Z-side. Hereinafter, a description and illustration will be given with reference to FIG. 2B and some subsequent drawings on the premise that the film 3 includes the conductive patterns GT, the wiring structures WR, the electrodes PD1, and the interlayer insulating film 40, for the sake of simplicity. Furthermore, the film 3 is regarded as a film that may be made of a material containing a semiconductor oxide (e.g., silicon oxide) as its main component because the interlayer insulating film 40 occupies most of the film 3 in terms of volume. It should be noted that the device structure illustrated in FIG. 3A is an example and is not particularly limited accordingly.

In preparing of the upper substrate (S3), a substrate (upper substrate) 100 is prepared, as illustrated in FIG. 2C. The substrate 100 may be made of, as its main material, a semiconductor material (e.g., silicon) that does not substantially contain impurities.

In forming of projections (S4), a principal surface 100b of the substrate 100 is processed, as illustrated in FIG. 2D. Multiple projections 101 are formed on the principal surface 100b (−Z-side surface) of the substrate 100 with dry etching, such as a reactive ion etching (RIE) method. For example, a photosensitive agent is applied to the principal surface 100b of the substrate 100. Then, a resist pattern RP (not illustrated) that selectively covers multiple areas corresponding to the multiple projections 101 on the principal surface 100b is formed with exposure and development. Etching is performed by using the resist pattern RP as a mask under the condition of anisotropic etching with the RIE method or any other suitable method, so that the multiple projections 101 are formed on the principal surface 100b of the substrate 100.

As illustrated in FIG. 4, the multiple projections 101 are formed so as to be distributed over the principal surface 100b in both the X and Y directions. The multiple projections 101 may be arranged in random directions in the X-Y plane.

Distances in the X and Y directions between the centers of mutually adjacent projections 101 out of the multiple projections 101 are defined as arrangement pitches. The arrangement pitches P between the multiple projections 101 may be substantially the same or may be different within a predetermined range. FIG. 4 illustrates an example of a layout configuration in which arrangement pitches P_1 to P_k between the multiple projections 101 are different within a first range. An average arrangement pitch P between the projections 101 may have a value within a second range (e.g., 0.1 μm to 10 μm). The average arrangement pitch P between the projections 101 may have a value obtained by averaging the arrangement pitches P_1 to P_k of the multiple projections 101.

Distances in the Z direction between the principal surface 100b and the ends of projections 101 are defined to as heights. Heights h of the projections 101 may be substantially the same or may be different within a third range. FIG. 2D illustrates a configuration in which the heights h of the projections 101 are substantially the same. An average height h of the projections 101 may have a value within the fourth range. The average height h of the projections 101 may have a value obtained by averaging the heights h of the multiple projections 101.

Maximum widths in the X and Y directions of the projections 101 at their ends are defined as end widths. The end widths W of the projections 101 may be substantially the same or may be different within a fifth range. FIG. 4 illustrates an example of a configuration in which the end widths W of the projections 101 are substantially the same. An average end width W of the projections 101 may have a value within a sixth range. An average end width W of the projections 101 may have a value obtained by averaging the end widths W of the multiple projections 101.

Values obtained by dividing the heights h of the projections 101 by the end widths W is defined as aspect ratios h/W. The aspect ratios h/W of the projections 101 may be substantially the same or may be different within the seventh range. FIG. 2D illustrates an example of a configuration in which aspect ratios h/W of the projections 101 are substantially the same. An average aspect ratio h/W of the projections 101 may have a value within an eighth range (e.g., 0.01 to 100). The average aspect ratio h/W of the projections 101 may have a value obtained by dividing the average height h of the projections 101 by the average end width W of the projections 101.

In forming of a film (S5), the film 4 that covers the multiple projections 101 is formed on the principal surface 100b of the substrate 100 with the CVD method or any other suitable method, as illustrated in FIG. 2E.

For example, the film 4, which includes the memory cell array structure MAR, may be formed, as illustrated in FIG. 3B. An insulating film 60 that covers the multiple projections 101 is deposited on the principal surface 100b of the substrate 100. Then, a conductive film is deposited and patterned. In this way, the conductive layer SL is formed. The insulating film 60 may be made of an insulating material, such as silicon oxide. The conductive layer SL may be made of a semiconductor material having conductivity, such as polysilicon containing impurities. Then, insulating layers and sacrificial layers (not illustrated) are alternately deposited multiple times on the +Z-side surface of the conductive layer SL, so that stacked bodies LM are formed. Each insulating layer may be made of an insulating material, such as silicon oxide. Each sacrificial layer may be made of an insulating material that can secure an etching selectivity to an insulating layer, such as silicon nitride. The insulating layers and the sacrificial layers can be deposited so as to have substantially the same film thickness.

A resist pattern is formed on the −Z-side surface of the stacked bodies so as to expose linear portions of the stacked bodies which extend in the Y direction. Anisotropic etching, such as the reactive ion etching (RIE) method, is performed using the resist pattern as a mask to form grooves across each stacked body LM in the Y and Z directions. Then, a separation film (not illustrated) is embedded in each groove. The separation film may be made of a material containing an insulating component (e.g., silicon oxide) as its main component. The separation film extends in the Y and Z directions on the −X-side surface of each stacked body LM. The separation film separates a stacked body LM from another stacked body LM disposed on the −X side. In each stacked body LM, the insulating layers and the sacrificial layers are alternately stacked multiple times. Each stacked body LM has a substantially rectangular shape, the long side of which extends in the Y direction in the X-Y planar view.

A resist pattern that has apertures at locations where memory holes are to be formed is formed on the −Z-side surface of each stacked body. Anisotropic etching, such as the RIE, is performed using the resist pattern as a mask, so that the memory holes are formed across each stacked body LM so as to reach the conductive layer SL.

On both the side surface and bottom of each memory hole, a block insulating film, a charge storage film, and a tunnel insulating film are deposited in this order. The block insulating film may be made of an insulating material, such as silicon oxide. Portions of the tunnel insulating film which corresponds to the bottoms of the memory holes are selectively peeled.

A semiconductor film is deposited on both the side surface and bottom of each memory hole. The semiconductor film may be made of a material containing a semiconductor component (e.g., polysilicon) as its main component. A core member is then embedded in each memory hole. The core member may be made of an insulating material, such as silicon oxide. As a result, multiple columnar bodies PL that penetrate each stacked body LM in the +Z direction are formed. The multiple columnar bodies PL are formed so as to be arrayed in both the X and Y directions.

The sacrificial layers of each stacked body LM are peeled. Block insulating films are formed on the exposed surfaces of gaps that have been formed by the peel. Each block insulating film may be made of an insulating material, such as aluminum oxide. Conductive layers WL are further embedded in each gap. Each conductive layer WL may be made of a material containing a conductive component (e.g., a metal such as tungsten) as its main component. As a result, each stacked body LM in which the conductive layers WL and the insulating layers are alternately and repeatedly stacked is formed. Memory cells are formed at locations where the conductive layers WL intersect the semiconductor films of the columnar bodies PL. In short, the memory cell array structure MAR in which the multiple memory cells are arrayed in a three-dimensional fashion are formed.

An interlayer insulating film 50 that covers the stacked bodies LM is further formed. By repeatedly forming a resist pattern and performing slimming and etching processes, a step structure in which the conductive layers WL are exposed stepwise from both sides of each stacked body LM in the Y direction is formed. By forming holes in the interlayer insulating film 50 and embedding a conductive material in the holes, for example, conductive plugs CC that are electrically connected to each conductive layer WL are formed. In addition to depositing the interlayer insulating film 50, holes are formed in the interlayer insulating film 50. Then, a conductive material is embedded in the holes, and a conductive pattern is formed. As a result, the wiring structure WR2 that is electrically connected to the conductive plugs CC is formed. On the principal surface 50a of the interlayer insulating film 50 which is disposed on the −Z side, electrodes PD2 each of which is electrically connected to the wiring structure WR2 are formed with plating or any other process. Hereinafter, a description and illustration will be given with reference to FIG. 2E and some subsequent drawings, for the sake of simplicity, on the premise that the film 4 includes the memory cell array structure MAR, the conductive plugs CC, the wiring structure WR2, the electrodes PD2, and the interlayer insulating films 50 and 60. In this case, the material of the film 4 is mainly regarded as the material of the interlayer insulating film 60 because the portion of the film 4 of interest in the present embodiment is the interlayer insulating film 60. It should be noted that the device structure illustrated in FIG. 3B is an example and is not particularly limited accordingly. Multiple memory cell array structures MAR may be formed, although a single memory cell array structure MAR is illustrated in FIG. 3B.

The film 4 may be made of any material whose infrared light absorption rate is higher than that of the substrate 100. The film 4 may be made of any material whose absorption rate for a laser wavelength (e.g., 9200 nm or more and 10800 nm or less) that is so suitable that the film 4 can function as a laser absorbing layer is higher than that of the substrate 100. The film 4 may be made of a material containing an insulating component as its main component or may be made of a material containing a semiconductor oxide (e.g., silicon oxide) as its main component.

As illustrated in FIG. 1, after both the process on the lower substrate (S1 and S2) and the process on the upper substrate (S3 to S5) have been completed, the upper substrate and the lower substrate are bonded together (S6). Both the principal surface 3a (see FIG. 2B) of the film 3 which is disposed on the +Z side and the principal surface 4b (see FIG. 2E) of the film 4 which is disposed on the −Z side are activated with plasma irradiation or any other suitable process. Then, as illustrated in FIG. 2F, the substrate 2 and the substrate 100 are disposed opposite each other in the Z direction with the principal surface 3a and the principal surface 4b facing each other. As illustrated in FIGS. 2F, 5A, and 6, the locations of the substrate 2 in the X and Y directions are aligned with those of the substrate 100 in such a way that the locations of the electrodes PD1 on the principal surface 3a in the X and Y directions relate to those of the electrodes PD2 on the principal surface 4b. As illustrated in FIGS. 5A and 6, the substrate 2 and the substrate 100 are moved closer to each other in the Z direction. Then, the principal surface 3a of the substrate 2 and the principal surface 4b of the substrate 100 are directly bonded together. In this case, the atoms in the principal surface 3a and the principal surface 4b are bonded (e.g., hydrogen-bonded) together, so that the substrate 2 and the substrate 100 are temporarily bonded.

For the above reason, as illustrated in FIG. 1, heat treatment (annealing) is performed at a relatively low temperature (S7). During the heat treatment (annealing), the entire substrate 2 and substrate 100 are heated, as indicated by dotted arrows in FIG. 5B. During the heat treatment, for example, both the substrate 2 and the substrate 100 are heated at a relatively low temperature (i.e., an allowable temperature of a device structure, such as about 200° C.) over a predetermined time. In this case, the atoms in the principal surface 3a and the atoms in the principal surface 4b are bonded (e.g., covalent-bonded) together because water molecules escape from the interface, so that the substrate 2 and the substrate 100 are finally bonded together. In this way, a bonded body CB is formed from the substrate 2 and the substrate 100. In this case, the electrode PD1 and the electrode PD2 are directly bonded together. The peripheral circuit structure PHC and the memory cell array structure MAR thereby can be electrically connected together.

After S7 illustrated in FIG. 1 has been completed, irradiation with laser beams 200 is performed from the substrate 100 with its focal point positioned near the film 4 (S8).

In the present embodiment, one irradiation with the laser beams 200 includes: a first step of irradiating the entire surface of the substrate 100 with the laser beams 200 to an N-th step of irradiating the entire surface of the substrate 100 with the laser beams 200. Here, N is any integer of 2 or more.

The laser beam irradiation is performed with the laser beam 200 having a wavelength band within which the light absorption rate of the film 4 serving as a laser absorption layer (when the laser absorption layer is a silicon oxide film, the thickness is preferably 1117 nm or more, more preferably near 9300 nm or near 10600 nm) is larger than that of the substrate 100. The laser beam 200 is a pulse laser. The laser beam 200 may be an infrared laser. The laser beam 200 may be a carbon dioxide laser (CO2 laser). The absorption of the laser beam 200 occurs depending on an absorption coefficient and thickness of a substrate or a film. In the present structure, the laser absorption occurs most in the film 4, which serves as a laser absorption layer.

In the above case, as illustrated in FIG. 7, the irradiation with the laser beams 200 is performed in such a way that spot areas 201 formed by the laser beam 200 are distributed in a two-dimensional fashion over the film 4, each spot area 201 having a larger diameter than the average arrangement pitch P between the projections 101. It is consequently possible to decrease the number of irradiation steps N to be performed for one irradiation with the laser beams 200, thereby shortening the overall time of the irradiation process required to remove the substrate 100, compared with a case where the diameter of each spot area 201 is as large as the average arrangement pitch P between the projections 101.

Each spot area 201 refers to an area irradiated with a corresponding laser beam 200 on the focal plane of the laser beam 200. In FIG. 7, each spot area 201 is surrounded by an alternate long and short dash line.

Each of the spot areas 201 formed the laser beams 200 may have a substantially circular shape in the X-Y plane view. When a spot area 201 has a substantially circular shape, a diameter of the spot area 201 is defined as a spot diameter. The spot diameter D of each laser beam 200 is larger than the average arrangement pitch P (see FIG. 4) between the projections 101 on the principal surface 100b of the substrate 100. The spot diameters D of the spot areas 201 may be substantially the same or may be different within a ninth range. FIG. 7 illustrates an example of an irradiation pattern in which the spot diameters D of the spot areas 201 are substantially the same. The average spot diameter D of the spot areas 201 may have a value within a tenth range (e.g., 10 μm to 1000 μm). The average spot diameter D of the spot areas 201 may have a value obtained by averaging the spot diameters D of the multiple spot areas 201.

A distance in the X and Y directions between the centers of mutually adjacent spot areas 201 out of the multiple spot areas 201 is defined as an irradiation pitch. Irradiation pitches LP between the multiple spot areas 201 may be substantially the same or may be different within an eleventh range. FIG. 7 illustrates an example of the irradiation pattern in which irradiation pitches LP_1 to LP_n between the multiple spot areas 201 are substantially the same. An average irradiation pitch LP between the spot areas 201 may have a value within a twelfth range (e.g., 10 μm to 1000 μm). The average irradiation pitch LP between the spot areas 201 may have a value obtained by averaging the irradiation pitches LP_1 to LP_n between the multiple spot areas 201.

The spot area 201 formed by each laser beam 200 overlaps two or more out of the projections 101 as viewed from the Z direction. More specifically, the spot area 201 formed by each laser beam 200 may include two or more out of the projections 101 inside as viewed from the Z direction. The numbers of projections 101 included in the multiple spot areas 201 may be substantially the same or may be different within a thirteenth range. FIG. 7 illustrates an example of the irradiation pattern in which the numbers of projections 101 included in the multiple spot areas 201 are substantially the same (e.g., three). The average number of the projections 101 included in the spot areas 201 may have a value within a fourteenth range (e.g., 100 to 1000). The average number of projections 101 included in the multiple spot areas 201 may be a value obtained by averaging the numbers of projections 101 included in the spot areas 201. The pitches P between the projections 101 are preferably the same. Accordingly, the spot areas 201 may move while overlapping one another so as to include a given number of projections 101.

The irradiation with the laser beams 200 may be performed while the spot areas 201 is moving along a spiral trajectory OB indicated by a dotted line in FIG. 7. If a laser irradiation device (not illustrated) equipped with a stage and a light source is used, the irradiation pattern made up of the spot areas 201 can be realized along the spiral trajectory OB from an outer peripheral location to a center location of the substrate 100. For this purpose, the bonded body CB (see FIG. 5B) formed of both the substrate 2 and the substrate 100 is first placed on the stage; and the light source is then gradually moved from the outer peripheral location to the center location while the stage is being rotated.

Alternatively, in the laser irradiation device equipped with the stage and the light source, the light source may be gradually moved from the center location to the outer peripheral location of the substrate while the stage is being rotated. In this case, the irradiation pattern made up of the spot areas 201 can be realized along the spiral trajectory OB from the center location to the outer peripheral location.

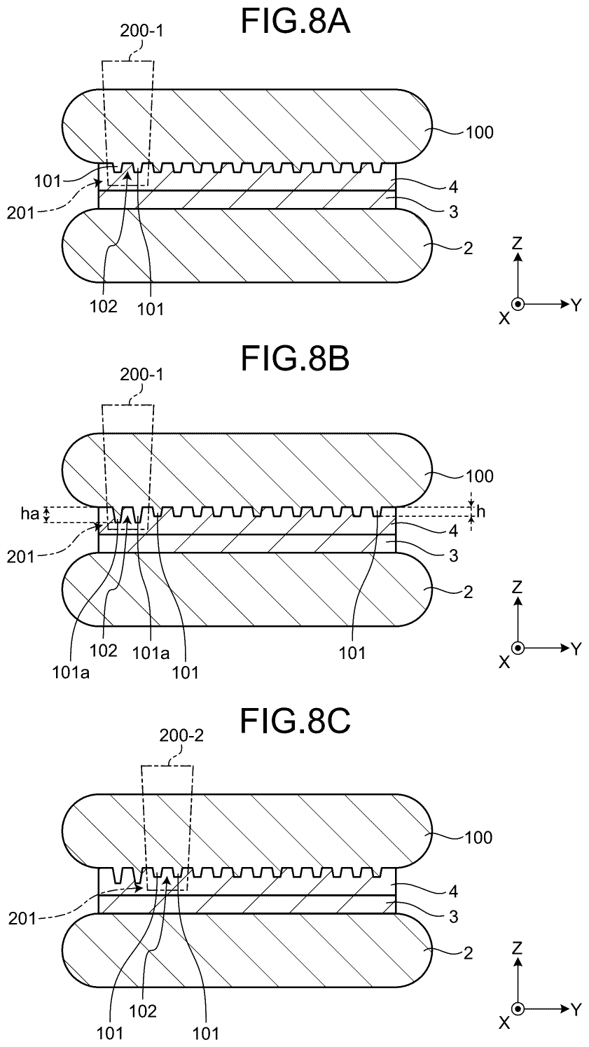

As illustrated in FIG. 8A, for example, an X-Y planar point to be irradiated with a laser beam 200-1 in the first irradiation step is first determined. The laser beam 200-1 is then adjusted in such a way that a focal point of the laser beam 200-1 is positioned on the film 4. The X-Y planar point to be irradiated may coincide with a start point in the spiral trajectory OB (see FIG. 7). The absorption rate of the film 4 for the laser beam 200-1 is larger than the absorption rate of the substrate 100 for the laser beam 200-1. As a result, the laser beam 200-1 with which the film 4 has been irradiated through the substrate 100 is efficiently absorbed by the irradiated portion of the film 4. In this way, the film 4 locally emits heat (is locally heated) at the irradiated X-Y planar point.

After having been locally generated in the film 4, the heat is transmitted to the interface between the film 4 and the substrate 100, as illustrated in FIG. 8B. The substrate 100 expands toward the film 4 at the heated X-Y planar point because the thermal expansion coefficient of the substrate 100 is higher than that of the film 4.

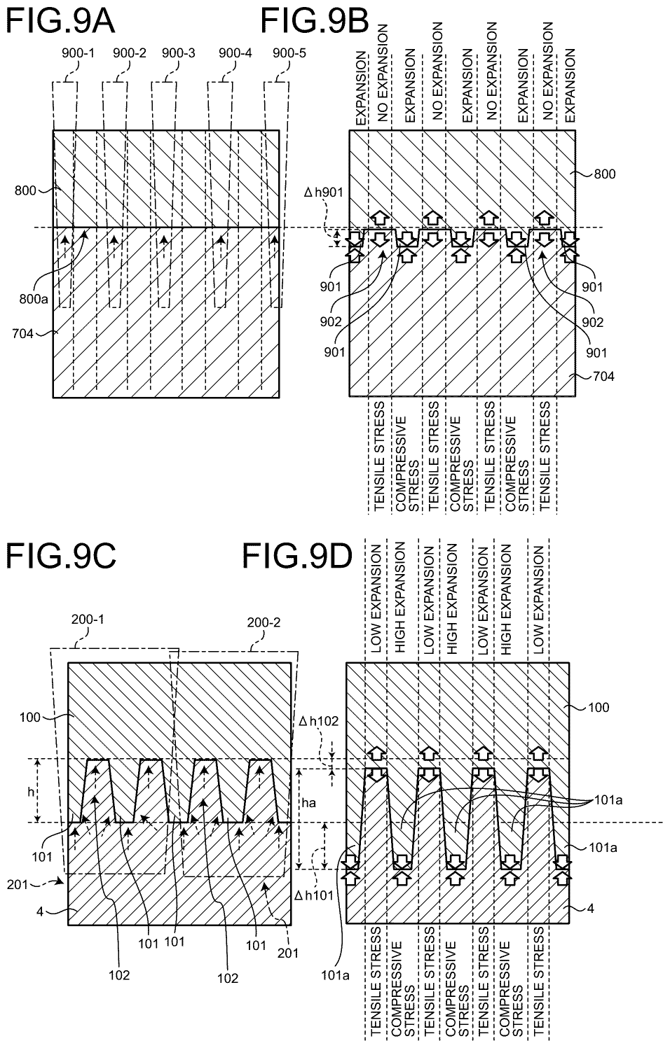

As illustrated in FIG. 9C, multiple projections 101 are included in each spot area 201 at the interface between the film 4 and the substrate 100. The −Z-side and outer-peripheral surfaces in the X and Y directions of the end of each projection 101 are in three-dimensional contact with the film 4, whereas the −Z-side surface, or the bottom, of a recess 102 positioned adjacent to each projection 101 is in two-dimensional contact with the film 4. Thus, as indicated by dotted arrows in FIG. 9C, the amount of heat transmitted from the film 4 to the end of each projection 101 is larger than that transmitted from the film 4 to the bottom of each recess 102.

As illustrated in FIG. 9D, an expansion amount Δh₁₀₁ in which the end of each projection 101a expands toward the film 4 is larger than an expansion amount Δh₁₀₂ in which the bottom of each recess 102 expands toward the film 4. As a result, compressive stress is generated at the interface between the end of each projection 101a and the film 4, whereas tensile stress is generated at the interface between the bottom of each recess 102 and the film 4.

The difference between the expansion amount Δh₁₀₁ and the expansion amount Δh₁₀₂ occurs within each spot area 201 at multiple points in the X and Y directions. As a result, the tensile stress at the interface between the bottom of the recess 102 and the film 4 is generated at multiple points in the X and Y directions within each spot area 201.

A height ha of the projections 101a within a spot area 201 is greater than a height h of the projections 101 outside the spot area 201 (ha>h).

As illustrated in FIG. 8C, the X-Y planar point to be irradiated with the laser beam 200-2 in the second irradiation step is determined to be a point shifted in the X and Y directions from the X-Y planar point in FIG. 8A. The laser beam 200-2 is then adjusted so that its focal point is positioned in the film 4. The point shifted in the X and Y directions from the X-Y planar point in FIG. 8A may coincide with one shifted from the start point along the spiral trajectory OB (see FIG. 7). The absorption rate of the film 4 for the laser beam 200-2 is larger than that of the substrate 100 for the laser beam 200-2. As a result, the laser beam 200-2 with which the film 4 has been irradiated through the substrate 100 is efficiently absorbed by the irradiated portion in the film 4, so that the film 4 locally emits heat (is locally heated) at the X-Y planar point.

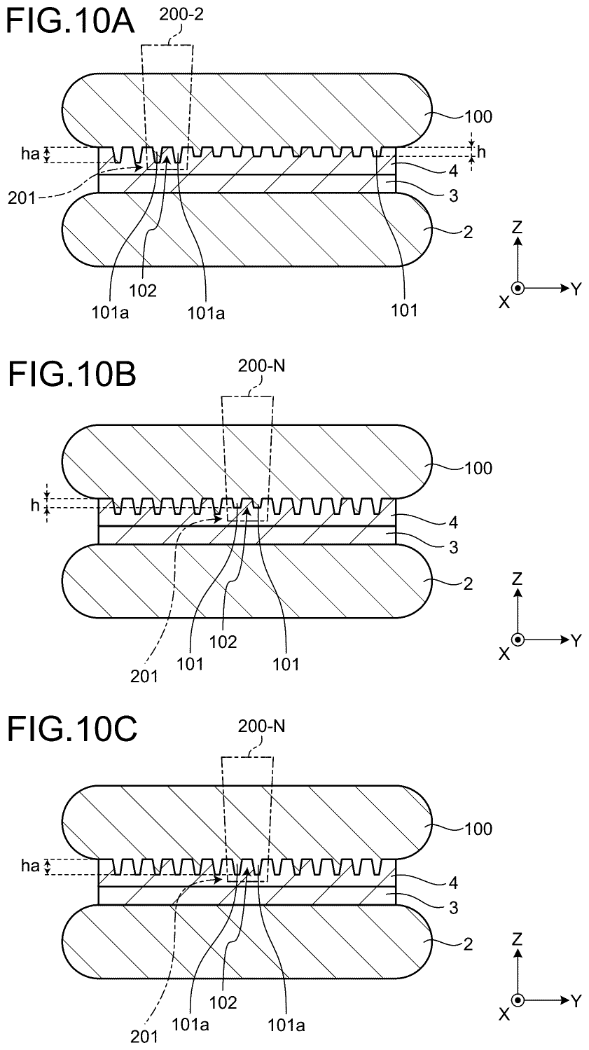

After having been locally generated in the film 4, the head is transmitted to the interface between the film 4 and the substrate 100, as illustrated in FIG. 10A. The substrate 100 expands toward the film 4 at the heated X-Y planar point because the thermal expansion coefficient of the substrate 100 is higher than that of the film 4.

As illustrated in FIG. 9C, multiple projections 101 are included in each spot area 201 at the interface between the film 4 and the substrate 100. The −Z-side and outer-peripheral surfaces in the X and Y directions of the end of each projection 101 are in three-dimensional contact with the film 4, whereas the −Z-side surface, or the bottom, of a recess 102 positioned adjacent to each projection 101 is in two-dimensional contact with the film 4. Thus, as indicated by dotted arrows in FIG. 9C, the amount of heat transmitted from the film 4 to the end of each projection 101 is larger than that transmitted from the film 4 to the bottom of each recess 102.

As illustrated in FIG. 9D, an expansion amount Δh₁₀₁ in which the end of each projection 101a expands toward the film 4 is larger than an expansion amount Δh₁₀₂ in which the bottom of each recess 102 expands toward the film 4. As a result, compressive stress is generated at the interface between the end of each projection 101a and the film 4, whereas tensile stress is generated at the interface between the bottom of each recess 102 and the film 4.

The difference between the expansion amount Δh₁₀₁ and the expansion amount Δh₁₀₂ occurs within each spot area 201 at multiple points in the X and Y directions. As a result, the tensile stress at the interface between the bottom of the recess 102 and the film 4 is generated at multiple points in the X and Y directions within each spot area 201.

A height ha of the projections 101a within a spot area 201 is greater than a height h of the projections 101 outside the spot area 201 (ha>h).

As illustrated in FIG. 10B, the last X-Y planar point to be irradiated with the laser beam 200-N in the N-th irradiation step is first determined. The laser beam 200-N is then adjusted in such a way that a focal point of the laser beam 200-N is positioned on the film 4. The last X-Y planar point to be irradiated may coincide with the last point in the spiral trajectory OB (see FIG. 7). The absorption rate of the film 4 for the laser beam 200-N is larger than that of the substrate 100 for the laser beam 200-N. As a result, the laser beam 200-N with which the film 4 has been irradiated through the substrate 100 is efficiently absorbed by the irradiated portion in the film 4, so that the film 4 locally emits heat (is locally heated) at the last X-Y planar point.

After having been locally generated in the film 4, the head is transmitted to the interface between the film 4 and the substrate 100, as illustrated in FIG. 10C. The substrate 100 expands toward the film 4 at the last X-Y planar point because the thermal expansion coefficient of the substrate 100 is higher than that of the film 4.

As illustrated in FIG. 9C, multiple projections 101 are included in each spot area 201 at the interface between the film 4 and the substrate 100. The −Z-side and outer-peripheral surfaces in the X and Y directions of the end of each projection 101 are in three-dimensional contact with the film 4, whereas the −Z-side surface, or the bottom, of a recess 102 positioned adjacent to each projection 101 is in two-dimensional contact with the film 4. Thus, as indicated by dotted arrows in FIG. 9C, the amount of heat transmitted from the film 4 to the end of each projection 101 is larger than that transmitted from the film 4 to the bottom of each recess 102.

As illustrated in FIG. 9D, an expansion amount Δh₁₀₁ in which the end of each projection 101a expands toward the film 4 is larger than an expansion amount Δh₁₀₂ in which the bottom of each recess 102 expands toward the film 4. As a result, compressive stress is generated at the interface between the end of each projection 101a and the film 4, whereas tensile stress is generated at the interface between the bottom of each recess 102 and the film 4.

The difference between the expansion amount Δh₁₀₁ and the expansion amount Δh₁₀₂ occurs within each spot area 201 at multiple points in the X and Y directions. As a result, the tensile stress at the interface between the bottom of the recess 102 and the film 4 is generated at multiple points in the X and Y directions within each spot area 201.

A height ha of the projections 101a within each spot area 201 is greater than a height h of the projections 101a that has not expanded (ha>h).

The irradiation with the laser beams 200 is performed in such a way that the multiple spot areas 201 are distributed in a two-dimensional fashion over the film 4. Consequently, as indicated by the dotted double arrows in FIG. 11, the tensile stress is generated on the bottoms of the multiple recesses 102 distributed in a two-dimensional fashion.

Next, peel is performed at the interface between the film 4 and the substrate 100 (S9). In the peel process, as illustrated in FIG. 12A, the substrate 100 is peeled from the stacked body 6 in which the film 3 and the film 4 are stacked on the substrate 2 in this order. The substrate 100 can be smoothly peeled from the stacked body 6 by using the bottoms of the multiple recesses 102 as initial points, for example, because the tensile stress is generated at the bottoms of the multiple recesses 102 distributed in a two-dimensional fashion.

In consideration of the subsequent process, for example, the peeling surface of the stacked body 6 is processed, as illustrated in FIG. 1 (S10). On the +Z-side surface, or the principal surface 4a, of the film 4 in the stacked body 6, as illustrated in FIG. 12B, multiple projections 4a2 are distributed in the X and Y directions. The principal surface 4a is thus polished and planarized by a CMP method or any other suitable process.

As a result of the above, as illustrated in FIG. 12C, the semiconductor device 1 is provided in which the film 3 and the film 4 are stacked on the substrate 2 and the principal surface 4a of the film 4 has been planarized.

After the planarization, for example, as illustrated in FIG. 13, holes are formed in the +Z-side surface, or the principal surface 60a, of the interlayer insulating film 60. Then, a conductive material is embedded in the holes, so that the conductive plugs PG that are electrically connected to the conductive layer SL are formed. An electrode pattern EL that is electrically connected to the conductive plugs PG is formed on the principal surface 60a of the interlayer insulating film 60 with plating or any other suitable process. In this case, another electrode pattern EL (not illustrated) that bypasses the memory cell array structure MAR and is connected to the peripheral circuit structure PHC is also formed on the principal surface 60a of the interlayer insulating film 60. In this way, both the memory cell array structure MAR and the peripheral circuit structure PHC can be supplied with electricity, a signal, and other information from an external source.

The film 4 including the memory cell array structure MAR can be regarded as a chip region for the memory cell array, whereas both the film 3 including the peripheral circuit structure PHC and the substrate 2 can be regarded as a chip region for the peripheral circuit. The semiconductor device 1 has a structure obtained by directly bonding the chip region for the memory cell array to the chip region for the peripheral circuit. This structure is also referred to as a “complementary metal oxide semiconductor (CMOS) directly bonded to array (CBA)”. In the CBA, a single chip region for the memory cell array does not necessarily have to be bonded to the +Z-side surface of the chip region for the peripheral circuit; alternatively, two or more chip region may be bonded.

After having been peeled, the substrate 100 will be reused, as illustrated in FIG. 1 (S11). The substrate 100 may be reused as the upper substrate 100, as indicated by the solid arrow in FIG. 1.

Immediately after the substrate 100 has been peeled, as illustrated in FIG. 12D, the multiple projections 101a are distributed in the X and Y directions over the principal surface 100b of the substrate 100 which is disposed on the −Z side. The principal surface 100b is thus polished and planarized with the CMP method or any other suitable method. As a result, as illustrated in FIG. 12E, the substrate 100 in which the principal surface 100b has been planarized is provided. The substrate 100 illustrated in FIG. 12E can be easily reused as the upper substrate 100, for example, because the principal surface 100b has been planarized.

Instead of being reused as the upper substrate 100, the peeled substrate 100 may be reused as the lower substrate 2, as indicated by the dotted arrow in FIG. 1.

As described above, in the first embodiment, in the method of manufacturing the semiconductor device 1, the multiple projections distributed in a two-dimensional fashion are formed on the principal surface 100b of the upper substrate 100. The irradiation with the laser beam 200 is then performed in such a way that the spot areas 201 formed by the laser beams 200 are distributed in a two-dimensional fashion over the film 4, each spot area 201 having a larger diameter than the average arrangement pitch P between the projections 101. After that, the upper substrate 100 is peeled. In this case, the irradiation with the laser beams 200 can differ the thermal expansion amounts of the ends of the projections and the bottoms of the recesses adjoining to the ends, thereby efficiently generating the tensile stress on the bottom of each recess. Moreover, a single laser beam irradiation process can differ the thermal expansion amounts at multiple locations within each spot area 201. This difference generates the tensile stress. It is consequently possible to decrease the number of irradiation steps N to be performed with the laser beams 200 for one irradiation, thereby shortening the overall time of the irradiation process required to remove the substrate 100, compared with a case where the diameter of each spot area 201 is as large as the average arrangement pitch P. Therefore, the throughput of laser peel can be efficiently improved.

The first embodiment can reduce the number of irradiation steps N using the laser beams 200 for one laser beam irradiation. As a result, in the laser irradiation step performed until the substrate 100 has been peeled, it is possible to decrease the amount of heat reaching the film 4 and/or the device structure (e.g., the device structure illustrated in FIG. 6) in the film 3, thereby successfully suppressing thermal damage to the device structure.

In a method of manufacturing a semiconductor device 1, for example, a comparative example will be considered in which multiple projections distributed in two-dimensional fashion are not formed on a principal surface 800a of an upper substrate 800 before irradiation with laser beams 900, as illustrated in FIG. 9A. In this case, multiple desired points are irradiated with the laser beams 900, a spot diameter of which is as large as that of desired locations. As a result, the projections 901 in the substantially same number in the irradiation steps are formed, as illustrated in FIG. 9B. As a result, compressive stress is generated at the interface between a film 704 and the ends of the projections 901, whereas tensile stress is generated at the interface between the film 704 and recesses 902 adjoining to the ends of the projections 901. In this case, the laser irradiation step of peeling the substrate 800 is prone to take time because the irradiation steps using the laser beams 900 are as many as locations where the tensile stress is to be generated.

The study associated with the above case reveals that, as the time interval between the irradiation steps using the laser beams 900 decreases (or the frequency of the irradiation increases) in accordance with an increase in the number of irradiation steps using the laser beams 900, the substrate 800 tends to be cooled at a lower rate, for example, due to thermal interference between multiple points irradiated with the laser beams 900. In such cases, the portions of the substrate 800 which expands toward the film 704 at the irradiated locations becomes less periodic in shape, thus making the forming of the recesses 902 difficult. As a result, the substrate 800 cannot be smoothly peeled because little tensile stress is generated at the interface between the substrate 900 and the film 704. In conclusion, it may be difficult to shorten the overall time required for the laser irradiation process even if the time interval between irradiation steps using the laser beams 900 is shortened.

In the first embodiment, however, multiple projections distributed in a two-dimensional fashion are formed on the surface of the upper substrate 100 before the irradiation with the laser beams 200, as illustrated in FIG. 9C. As a result, as illustrated in FIGS. 9C and 9D, a single step of the irradiation with the laser beams can differ the thermal expansion amounts at multiple locations within each spot area 201, thereby generating tensile stress. Thus, a number of locations where tensile stress is generated can be smaller than that of irradiation steps using the laser beams 900. If tensile stress is generated at five locations as in the case of FIG. 9A, for example, it is necessary to irradiate these locations with five laser beams (laser beams 900-1 to 900-5). In the case of FIG. 9C, however, it is only necessary to irradiate the locations with two laser beams (laser beams 200-1 and 200-2). It is consequently possible to decrease the number N of irradiation steps using the laser beams 200 and to shorten the overall time required for the laser irradiation process of peeling the substrate 100.

When the method of manufacturing the semiconductor device 1 is performed, if multiple projections distributed in a two-dimensional fashion is not formed on the surface of the upper substrate 800 before the irradiation with the laser beams 900, a smaller amount of heat is transmitted to the substrate 800 during the irradiation with the laser beams 900, as indicated by the dotted arrows in FIG. 9A. Therefore, as illustrated in FIG. 9B, the difference between a thermal expansion amount Δh₉₀₁ of the end of each projection 901 and a thermal expansion amount (≈0) of the bottom of each recess 902 becomes relatively small. In such cases, the tensile stress generated on the bottom of each recess tends to be small.

In the first embodiment, however, the multiple projections 101 distributed in a two-dimensional fashion are formed on the surface of the upper substrate 100, as illustrated in FIG. 9D. This can reliably secure a large difference between the expansion amount Δh₁₀₁ of the end of each projection 101a and the expansion amount Δh₁₀₂ of the bottom of each recess 102. It is consequently possible to efficiently generate the tensile stress on the bottom of each recess 102.

### First Modification of First Embodiment

In a first modification of the foregoing first embodiment, the spot areas 201 formed by the laser beams 200 may have shapes other than a substantially circular one in X-Y plan view. Each spot area 201 may have any shape suitable for laser peel. Spot areas 201p formed by respective laser beams 200p do not have to be formed into the same shape by a single irradiation step using the laser beams 200p. In other words, the spot areas 201p may be formed into different shapes from the first irradiation step using the laser beams 200p through the N-th irradiation step using the laser beams 200p.

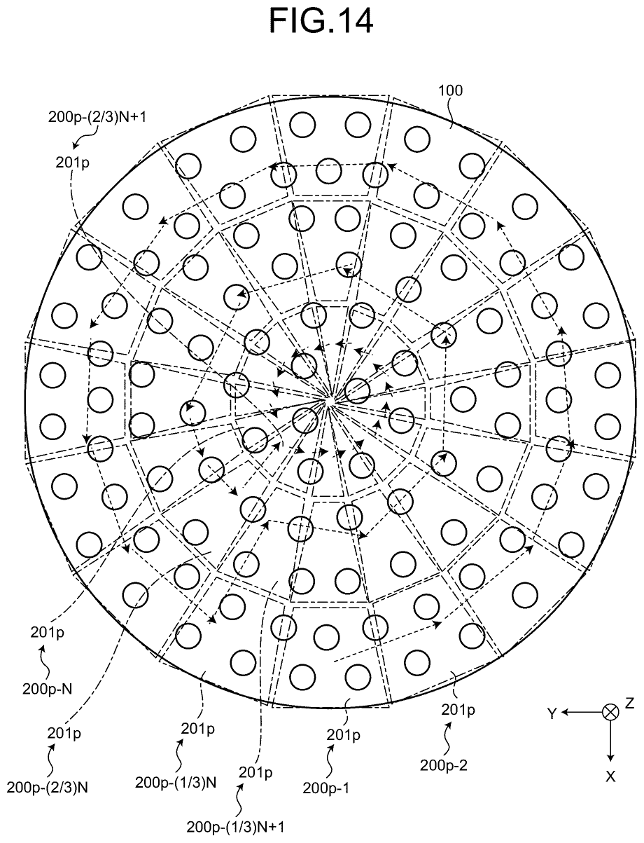

Suppose N is a multiple of 3, as illustrated in FIG. 14, for example. Spot areas 201p formed in a first irradiation step using the laser beams 200p-1 to a (1/3)N-th irradiation step using a laser beam 200p-(1/3) N may each have a relatively large substantially trapezoidal shape. Spot areas 201p formed in a {(1/3) N+1}-th irradiation step using laser beams 200p-(1/3) N+1 to a (2/3)N-th irradiation step using laser beams 200p-(2/3) N may each have a smaller substantially trapezoidal shape. Spot areas 201p formed in a {(2/3) N+1}-th irradiation step using a laser beam 200p-(2/3) N+1 to an N-th irradiation step using a laser beam 200p-N may each have a smaller substantially triangular shape. In the case illustrated in FIG. 14, with a single irradiation step using the laser beams 200p, the spot areas 201p can be arranged efficiently and closely over a substrate 100.

### Second Modification of First Embodiment

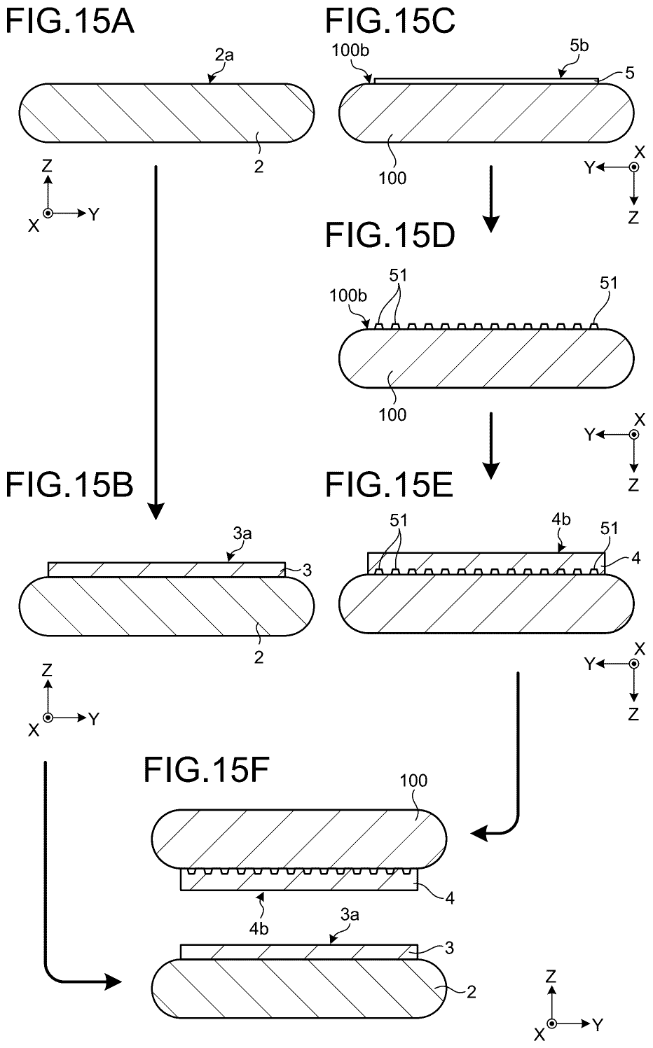

In a second modification of the first embodiment, the forming of projections (S4) may be performed by processing a film 5 disposed on a substrate 100, as illustrated in FIGS. 15A to 15F, instead of processing a principal surface 100b of the substrate 100. FIGS. 15A to 15F are Y-Z cross-sectional views each illustrating a method of manufacturing a semiconductor device 1 according to the second modification of the first embodiment.

Preparing of a lower substrate (S1) as illustrated in FIG. 15A and forming of a film (S2) as illustrated in FIG. 15B are both performed in the same manner as in the first embodiment.

In preparing of an upper substrate (S3) as illustrated in FIG. 15C, the substrate (upper substrate) 100 is prepared, and then the film 5 is deposited on the principal surface 100b of the substrate 100 by the CVD method or any other suitable process. The film 5 may be made of a material containing a semiconductor nitride (e.g., silicon nitride) as its main component or may be made of a material containing a semiconductor component (e.g., polysilicon) as its main component. Alternatively, the film 5 may be epitaxially grown on the principal surface 100b of the substrate 100. The film 5 may be made of a material containing a semiconductor component (e.g., silicon) as its main component.

Forming of projections (S4) as illustrated in FIG. 15D may be performed by processing the film 5. Multiple projections 51 are formed on the film 5 by dry etching, such as the RIE method. For example, a photosensitive agent is applied to the principal surface 5b of the film 5. Then, a resist pattern RP (not illustrated) that selectively covers multiple areas corresponding to the multiple projections 51 on the principal surface 5b is formed with exposure and development. Etching is performed by using the resist pattern RP as a mask under the condition of anisotropic etching with the RIE method or any other suitable method, so that the multiple projections 51 are formed on the principal surface 100b of the substrate 100.

As illustrated in FIG. 4, the multiple projections 51 are formed so as to be distributed in the X and Y directions over the principal surface 100b, similar to the first embodiment.

In forming of a film (S5) as illustrated in FIG. 15E, a film 4 that covers the multiple projections 51 is deposited by the CVD method or any other suitable process.

After both the process on the lower substrate (S1 and S2) and the process on the upper substrate (S3 to S5) have been completed, the upper substrate and the lower substrate are bonded together (S6). In this case, both the principal surface 3a of the film 3 which is disposed on the +Z side and the principal surface 4b of the film 4 which is disposed on the −Z side are activated with plasma irradiation or any other suitable process. Then, as illustrated in FIG. 15F, a substrate 2 and the substrate 100 are disposed opposite each other in the Z direction with the principal surface 3a and the principal surface 4b facing each other. As illustrated in FIG. 5A, the substrate 2 and the substrate 100 are made closer to each other in the Z direction. Then, the principal surface 3a of the substrate 2 and the principal surface 4b of the substrate 100 are bonded together.

S7 and the remaining subsequent steps illustrated in FIG. 1 are performed in the same manner as in the first embodiment.

With the above process steps, the multiple projections 51 distributed in a two-dimensional fashion can also be formed on the principal surface 100b of the upper substrate 100.

### Third Modification of First Embodiment

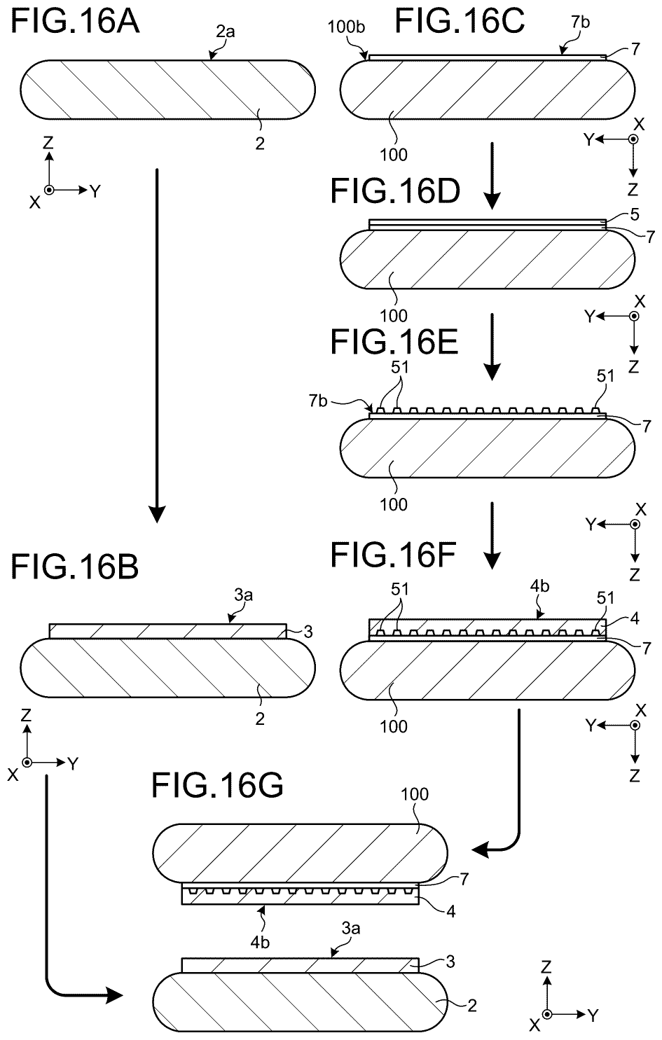

In a third modification of the first embodiment, forming of projections (S4) may be performed by processing a film 5 disposed over a film 7 on a substrate 100, as illustrated in FIGS. 16A to 16G, instead of processing a principal surface 100b of the substrate 100. FIGS. 16A to 16G are Y-Z cross-sectional views illustrating a method of manufacturing a semiconductor device 1 according to the third modification of the first embodiment.

Preparing of a lower substrate (S1) as illustrated in FIG. 16A and forming of a film (S2) as illustrated in FIG. 16B are both performed in the same manner as in the first embodiment.

In preparing of an upper substrate (S3) as illustrated in FIG. 16C, the substrate (upper substrate) 100 is prepared, and then the film 7 is deposited on the principal surface 100b of the substrate 100 by the CVD method or any other suitable process. The film 7 may be made of a material containing a semiconductor nitride (e.g., silicon nitride) as its main component.

As illustrated in FIG. 16D, the film 5 is deposited on a principal surface 7b of the film 7 by the CVD method or any other suitable process. The film 5 may be made of a material containing a semiconductor component (e.g., polysilicon) as its main component.

Forming of the projections (S4) as illustrated in FIG. 16E may be performed by processing the film 5. Multiple projections 51 are formed on the film 5 by dry etching, such as the RIE method. For example, a photosensitive agent is applied to the principal surface 5b of the film 5. Then, a resist pattern RP (not illustrated) that selectively covers multiple areas corresponding to the multiple projections 51 on the principal surface 5b is formed with exposure and development. Etching is performed by using the resist pattern RP as a mask under the condition of anisotropic etching with the RIE method or any other suitable method, so that the multiple projections 51 are formed on the principal surface 7b of the film 7.

As illustrated in FIG. 4, the multiple projections 51 are formed so as to be distributed in the X and Y directions over the principal surface 100b, similar to the first embodiment.

In forming a film (S5), the film 4 that covers the multiple projections 51 is deposited on the principal surface 7b of the film 7 with the CVD method or any other suitable method, as illustrated in FIG. 16F.

After both the process on the lower substrate (S1 and S2) and the process on the upper substrate (S3 to S5) have been completed, the upper substrate and the lower substrate are bonded together (S6). Both a principal surface 3a of a film 3 which is disposed on the +Z side of a substrate 2 and the principal surface 4b of the film 4 which is disposed on the −Z side are activated with plasma irradiation or any other suitable process. Then, as illustrated in FIG. 16G, the substrate 2 and the substrate 100 are disposed opposite each other in the Z direction with the principal surface 3a and the principal surface 4b facing each other. As illustrated in FIG. 5A, the substrate 2 and the substrate 100 are made closer to each other in the Z direction. Then, the principal surface 3a of the substrate 2 and the principal surface 4b of the substrate 100 are bonded together.

S7 and the remaining subsequent steps illustrated in FIG. 1 are performed in the same manner as in the first embodiment.

With the above process steps, the multiple projections 51 distributed in a two-dimensional fashion can also be formed on the principal surface 100b of the upper substrate 100.

### Second Embodiment

Next, a method of manufacturing the semiconductor device 1 according to the second embodiment will be described. The features in the second embodiment which are different from the foregoing first embodiment will be mainly described below.

In the case of FIG. 9A, as mentioned above, as the time interval between the irradiation steps using the laser beams 900 decreases in accordance with an increase in the number of irradiation steps using the laser beams 900, the substrate tends to be cooled at a lower rate, for example, due to thermal interference between multiple locations irradiated with the laser beams 900. In such cases, the portions of the substrate which expands toward the film 704 at the irradiated locations becomes less periodic in shape, thus making the forming of the recesses 902 difficult. As a result, the substrate 800 cannot be smoothly peeled because little tensile stress is generated at the interface between the substrate 900 and the film 704.

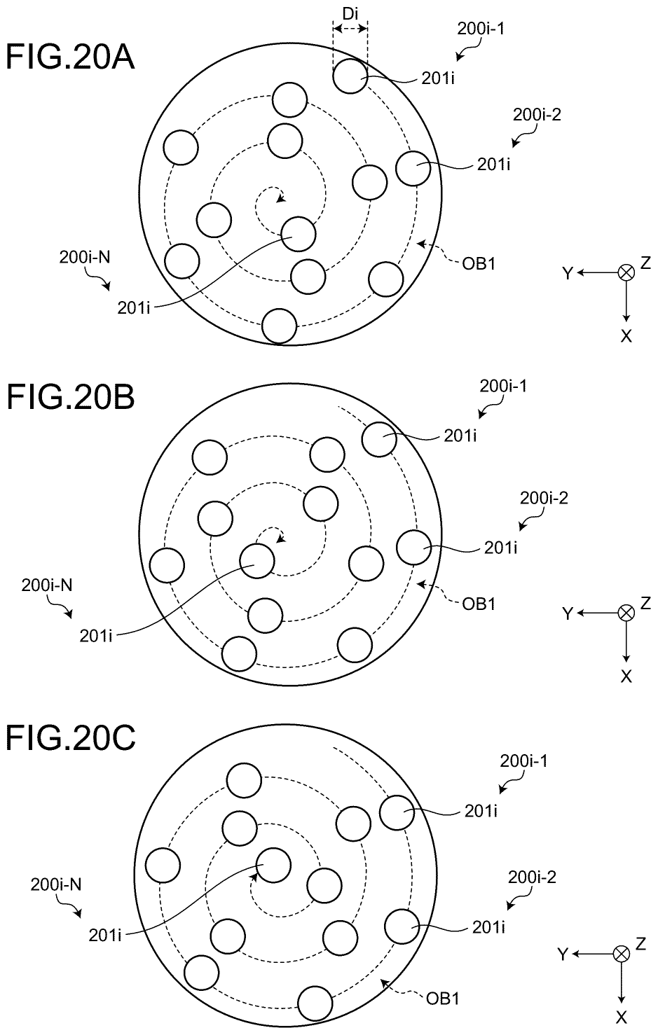

In the second embodiment, as illustrated in FIGS. 20A to 20C to be referenced later, irradiation with laser beams 200i is separately performed on multiple segments along a trajectory OB1. This multi-segment irradiation aims to improve the throughput of the laser peel with thermal interference between the irradiated points suppressed.

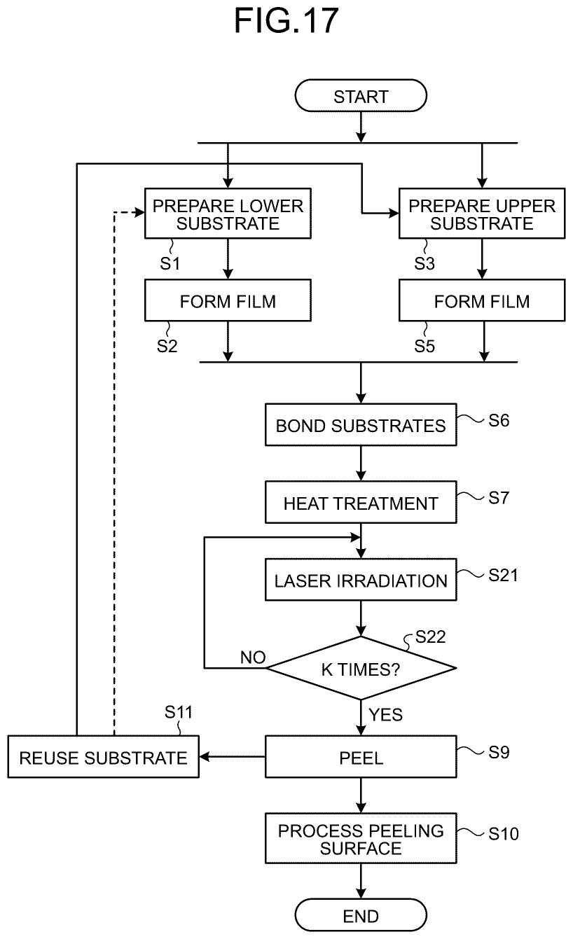

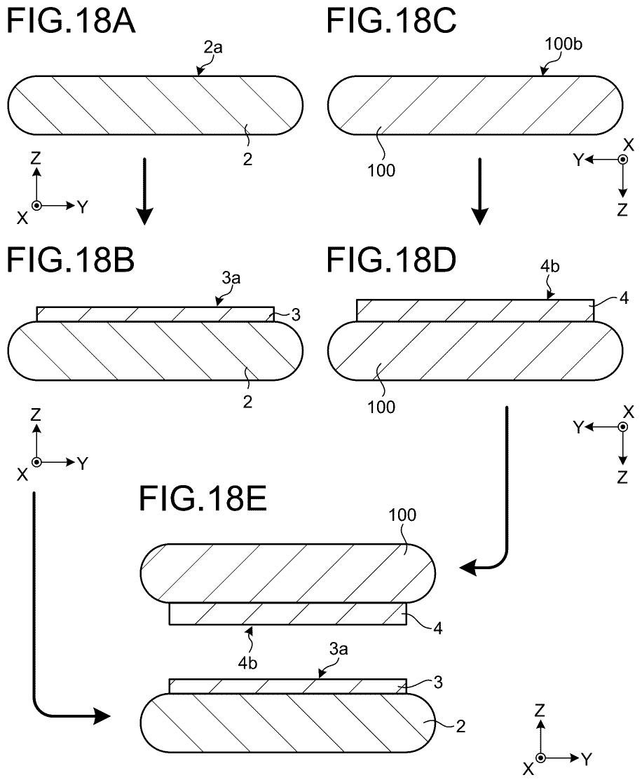

As illustrated in FIGS. 17 to 22, for example, a method of manufacturing the semiconductor device 1 is different from that in the first embodiment in some features that will be described below. FIG. 17 is a flowchart illustrating the method of manufacturing the semiconductor device 1. FIGS. 18A to 18F, 19A to 19B, 21A to 21D, and 22 are each a Y-Z cross-sectional view illustrating the method of manufacturing the semiconductor device 1. FIGS. 20A to 20D are X-Y plan views illustrating a multi-segment irradiation pattern.

In the method of manufacturing the semiconductor device 1, as illustrated in FIG. 17, S4 (see FIG. 1) is not performed, and S21 and S22 are newly performed instead of S8 (see FIG. 1).

Preparing of a lower substrate (S1) as illustrated in FIG. 18A and forming of a film (S2) as illustrated in FIG. 18B are both performed in the same manner as in the first embodiment.

Preparing of an upper substrate (S3) as illustrated in FIG. 18C is performed in the same manner as the first embodiment; however, forming of a film (S5) is different from that in the first embodiment in that the film 4 is deposited on a flat principal surface 100b of a substrate 100, as illustrated in FIG. 18D.

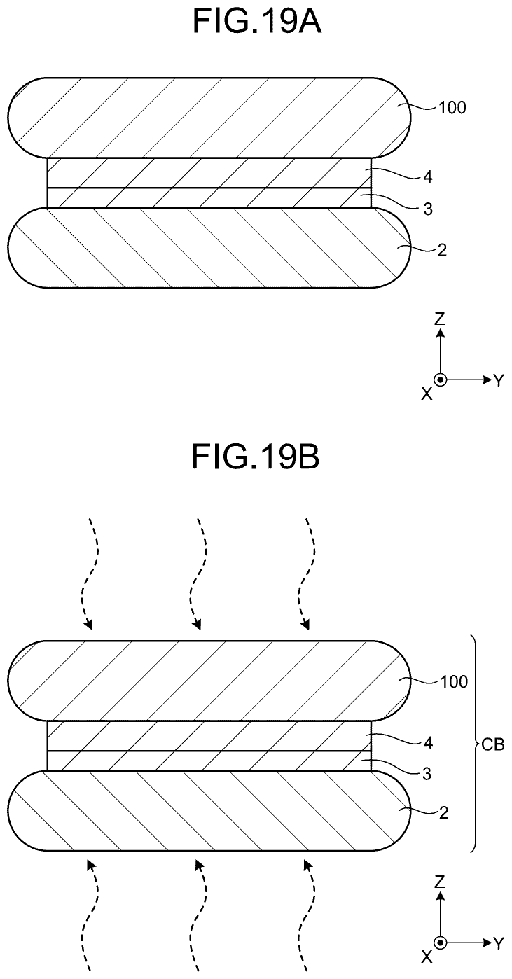

After both the process on the lower substrate (S1 and S2) and the process on the upper substrate (S3 to S5) have been completed, the upper substrate and the lower substrate are bonded together (S6). Both a principal surface 3a of a film 3 which is disposed on the +Z side of a substrate 2 and a principal surface 4b of the film 4 which is disposed on the −Z side are activated with plasma irradiation or any other suitable process. Then, as illustrated in FIG. 18E, the substrate 2 and the substrate 100 are disposed opposite each other in the Z direction with the principal surface 3a and the principal surface 4b facing each other. As illustrated in FIG. 19A, the substrate 2 and the substrate 100 are moved closer to each other in the Z direction. Then, the principal surface 3a of the substrate 2 and the principal surface 4b of the substrate 100 are bonded together.

Following the above, as illustrated in FIG. 17, heat treatment (annealing) is performed at a relatively low temperature (S7). During the heat treatment (annealing), the entire substrate 2 and substrate 100 are heated, as indicated by the dotted arrows in FIG. 19B. In this way, a bonded body CB is formed from the substrate 2 and the substrate 100.

After S7 illustrated in FIG. 17 has been completed, the substrate 100 is irradiated with laser beams 200i with its focal point positioned near the film 4 (S21).

In the above case, the irradiation with the laser beams 200i may be K-time multi-segment irradiations to be performed along the trajectory OB1. Here, K is an integer of 2 or more. Optionally, a parameter for use in counting the number of times that the multi-segment irradiation has been performed may be prepared. For example, the parameter may be set to an initial value “1” for a first multi-segment irradiation. Then, whenever the number of times that the multi-segment irradiation has been performed increases, the parameter may be incremented.

Here, assume that the substrate 100 can be peeled off (S9) by irradiating the entire surface of the substrate with a first step of irradiating the laser beams 200 to a L-th step as a last step of irradiating the laser beams 200 along a trajectory OB1 at a single time. At this time, the irradiation pitch when the laser beam is irradiated to the trajectory OB1 over the entire surface of the substrate 100 at the single time shall be referred to as a “pre-segmentation pitch”.

In the present embodiment, the multi-segment irradiation means the separating of one (the single time) irradiation with the laser beams 200i into K-time irradiations with laser beams, each irradiation including a first step of irradiating the entire surface of the substrate with the laser beams 200 to an N-th step of irradiating the entire surface of the substrate 100 with the laser beams 200, where L=(K×N). Here, L and N are an integer of 2 or more.

For the K-time multi-segment irradiations, respective irradiation patterns may be formed in such a way that their start points are shifted from one another at a distance away with the pre-segmentation pitch. The pre-segmentation pitch may be substantially equal to or slightly different from a size of spot areas formed by one irradiation and in such a way that spot areas are arranged along the trajectory OB1 at a pitch equal to K times the pre-segmentation pitch formed by the one irradiation. In other words, for the K-time multi-segment irradiations, their start points are shifted from one another at a distance away which is substantially the same as a size of spot areas. The trajectory OB1 may have a spiral shape as viewed from the Z direction.

In a case of K=3, for example, the irradiation patterns may be formed, as illustrated in FIGS. 20A to 20C. FIG. 20A illustrates an example of a first multi-segment irradiation pattern; FIG. 20B illustrates an example of a second multi-segment irradiation pattern; and FIG. 20C illustrates an example of a third multi-segment irradiation pattern. FIGS. 20A to 20C illustrate an example case where spot areas 201i have a circular shape.

As illustrated in FIGS. 20A to 20C, the start points of the first multi-segment irradiation pattern, the second multi-segment irradiation pattern, and the third multi-segment irradiation pattern are shifted from one another at a distance away with the pre-segmentation pitch. The pre-segmentation pitch may be substantially equal to or slightly different from a spot diameter Di of the spot areas 201i for one irradiation, for example.

As illustrated in FIG. 20A, the first multi-segment irradiation pattern is formed of the spot areas 201i arranged along the trajectory OB1 at a pitch equal to three times the pre-segmentation pitch. As illustrated in FIG. 20B, the second multi-segment irradiation pattern is formed of the spot areas 201i arranged along the trajectory OB1 at a pitch equal to three times pre-segmentation pitch. As illustrated in FIG. 20C, the third multi-segment irradiation pattern is formed of the spot areas 201i arranged along the trajectory OB1 at a pitch equal to three times the pre-segmentation pitch.

In the above way, each multi-segment irradiation can form temporally adjacent spot areas 201i so as to be arranged at a sufficiently long spatial distance away. This can perform the irradiation steps using the laser beams 900 at a short time interval (or at a high irradiation frequency) with the thermal interference between the temporally adjacent spot areas 201i suppressed.

For each multi-segment irradiation pattern, the irradiation number N (i.e., the number N of spot areas 201i) of the laser beams 200i may be equal to each other. The present embodiment provides an example of the irradiation patterns each of which are formed of the spot areas 201i that starts from the outer peripheral location and ends at the center location on the spiral trajectory OB1. As an alternative example, however, each irradiation pattern may be formed of the spot areas 201i that start from the center location to end at the outer peripheral location on the spiral trajectory OB1.

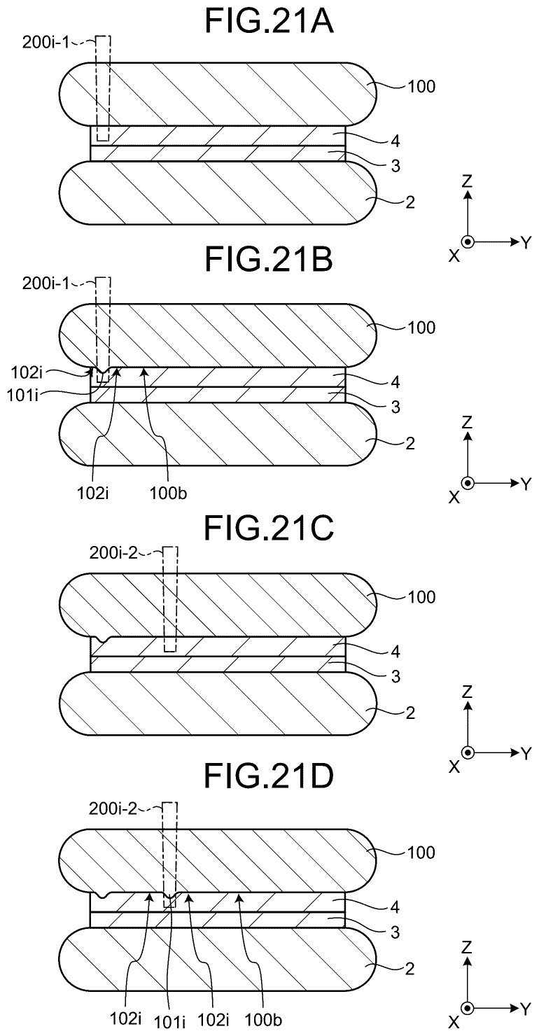

As illustrated in FIG. 21A, for example, an X-Y planar point to be irradiated with a laser beam 200i-1 in the first irradiation step is first determined. The laser beam 200i-1 is then adjusted in such a way that a focal point of the laser beam 200i-1 is positioned on the film 4. If the first multi-segment irradiation pattern is formed, the X-Y planar point to be irradiated may coincide with the start point illustrated in FIG. 20A. Likewise, if the second multi-segment irradiation pattern is formed, the X-Y planar point may coincide with the start point illustrated in FIG. 20B. If the third multi-segment irradiation pattern is formed, the X-Y planar point may coincide with the start point illustrated in FIG. 20C. The absorption rate of the film 4 for the laser beam 200-1 is larger than the absorption rate of the substrate 100 for the laser beam 200-1. As a result, the laser beam 200-1 with which the film 4 has been irradiated through the substrate 100 is efficiently absorbed by the irradiated portion of the film 4. In this way, the film 4 locally emits heat (is locally heated) at the irradiated X-Y planar point.

After having been locally generated in the film 4, the heat is transmitted to the interface between the film 4 and the substrate 100, as illustrated in FIG. 21B. The substrate 100 expands toward the film 4 at the heated X-Y planar point because the thermal expansion coefficient of the substrate 100 is higher than that of the film 4. As a result, a projection 101i that protrudes to the −Z side is formed on a principal surface 100b of the substrate 100 at the X-Y planar point. In response, compressive stress is generated at the interface between a film 4 and the end of the projection 101i, whereas tensile stress is generated at the interface between the film 4 and a recess 102i adjoining to the end of the projection 101i.

As illustrated in FIG. 21C, an X-Y planar point to be irradiated with the laser beam 200i-2 in the second irradiation step is determined to be a point shifted in the X and Y directions from the X-Y planar point in FIG. 21A. The laser beam 200i-2 is then adjusted so that its focal point is positioned in the film 4. If the first multi-segment irradiation pattern is formed, the point shifted in the X and Y directions from the X-Y planar point in FIG. 21A may coincide with a point shifted at a pitch equal to three times the pre-segmentation pitch along the trajectory OB1 from the start point illustrated in FIG. 20A. Likewise, if the second multi-segment irradiation pattern is formed, the shifted point may coincide with a point shifted at a pitch equal to three times the pre-segmentation pitch along the trajectory OB1 from the start point illustrated in FIG. 20B. If the third multi-segment irradiation pattern is formed, the shifted point may coincide with a point shifted at a pitch equal to three times the pre-segmentation pitch along the trajectory OB1 The from the start point illustrated in FIG. 20C. The absorption rate of the film 4 for the laser beam 200i-2 is larger than that of the substrate 100 for the laser beam 200i-2. As a result, the laser beam 200i-2 with which the film 4 has been irradiated through the substrate 100 is efficiently absorbed by the irradiated portion in the film 4, so that the film 4 locally emits heat (is locally heated) at the X-Y planar point.

After having been locally generated in the film 4, the heat is transmitted to the interface between the film 4 and the substrate 100, as illustrated in FIG. 21D. The substrate 100 expands toward the film 4 at the heated X-Y planar point because the thermal expansion coefficient of the substrate 100 is higher than that of the film 4.

In the above case, the X-Y planar point irradiated in FIG. 21D is positioned apart from the X-Y planar point irradiated in FIG. 21B at a pitch equal to three times the pre-segmentation pitch, so that thermal interference from the X-Y planar point in FIG. 21B is suppressed.

In response to the above, the substrate 100 expands toward the film 4 at the X-Y planar point in FIG. 21D. In this case, a projection 101i that protrudes toward the −Z side is formed on the principal surface 100b of the substrate 100 at the X-Y planar point. As a result, compressive stress is generated at the interface between the film 4 and the end of the projection 101i, whereas tensile stress is generated at the interface between the film 4 and the bottom of a recess 102i adjoining to the end of the projection 101i.

After the irradiation with the laser beams 200i is performed likewise up to the N-th time, it is determined whether the current multi-segment irradiation coincides with the K-th multi-segment irradiation (S22). For example, when the parameter for use in counting the number of times that the multi-segment irradiation has been performed is checked, if the value of the parameter is less than K, it is determined that the current multi-segment irradiation does not yet coincide with the K-th multi-segment irradiation (No in S22). In this case, the process is returned to S21.

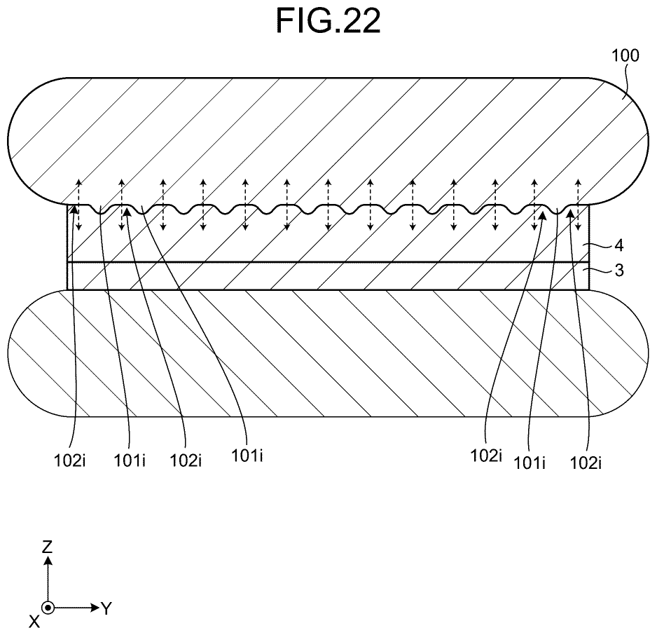

The irradiation with the laser beams 200i is separately performed the K-th times in such a way that the multiple spot areas 201i are distributed in a two-dimensional fashion over the film 4. Consequently, as indicated by the dotted double arrows in FIG. 22, the tensile stress is generated on the bottoms of the multiple recesses 102i distributed in a two-dimensional fashion.

For example, when the parameter for use in counting the number of times that the multi-segment irradiation has been performed is checked, if the value of the parameter is equal to or more than K, it is determined that the current multi-segment irradiation coincides with the K-th multi-segment irradiation (Yes in S22). In this case, the peel is performed at the interface between the film 4 and the substrate 100 (S9). This peel is performed in the same manner as in the first embodiment.

After having been peeled, the substrate 100 is reused, as illustrated in FIG. 17 (S11). The substrate 100 may be reused as the upper substrate 100, as indicated by the solid arrow in FIG. 17. The reuse is performed in the same manner as the first embodiment.

Instead of being reused as the upper substrate 100, the peeled substrate 100 may be reused as the lower substrate 2, as indicated by the dotted arrow in FIG. 17.

In the method of manufacturing the semiconductor device 1 according to the second embodiment, as described above, the irradiation with the laser beams 200i is separately performed on multiple segments along the trajectory OB1. It is thereby possible to perform irradiation steps using the laser beams 200i at a short time interval (or at a high irradiation frequency) with the thermal interference between irradiated points suppressed. Consequently, the throughput of laser peel can be improved.

It should be noted that, as illustrated in FIGS. 20A to 20C, as the radius of the spiral trajectory OB1 decreases from the outer peripheral location toward the central location, the X and Y distances between the temporally adjacent (e.g., one to three previous) spot areas 201i tend to decrease. Accordingly, as a point to be irradiated moves from the outer peripheral location toward the central location, it is more difficult to shorten the distances in the X and Y directions between the spot areas 201i while keeping the irradiation time interval constant. It may be necessary to use a complicated mechanism for controlling the irradiation time interval between the laser beams 200i.

### First Modification of Second Embodiment

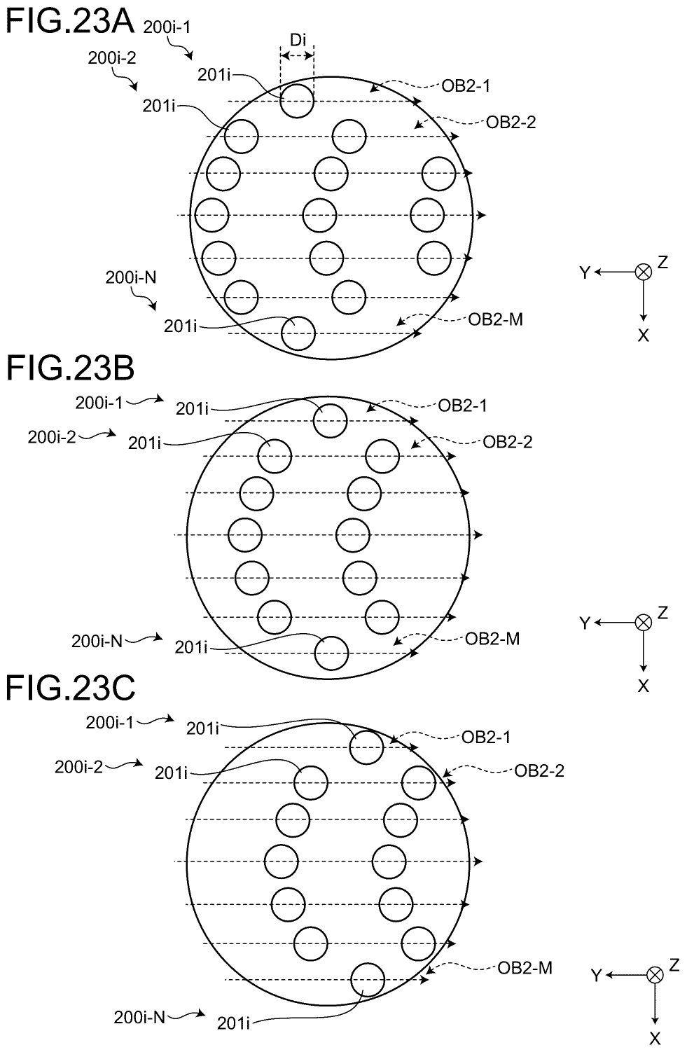

In consideration of the above disadvantage, in a first modification of the foregoing second embodiment, K-time multi-segment irradiations may be performed along multiple linear trajectories OB2, as illustrated in FIGS. 23A to 23C. FIGS. 23A to 23C are X-Y planar views illustrating respective multi-segment irradiation patterns according to the first modification of the second embodiment.

In a case of K=3, for example, three multi-segment irradiation patterns may be formed, as illustrated in FIGS. 23A to 23C. FIG. 23A illustrates an example of a first multi-segment irradiation pattern; FIG. 23B illustrates an example of a second multi-segment irradiation pattern; and FIG. 23C illustrates an example of a third multi-segment irradiation pattern. FIGS. 23A to 23C illustrate an example case where spot areas 201i each have a circular shape.

As illustrated in FIGS. 23A to 23C, multiple trajectories OB2-1 to OB2-M are used for the K-time multi-segment irradiations. Here, M is any integer of 2 or more. The multiple trajectories OB2-1 to OB2-M extend substantially parallel to one another while arranged at substantially constant intervals in a direction perpendicular to the extending direction. In the case of FIGS. 23A to 23C, each of the trajectories OB2-1 to OB2-M extends in the Y direction. The multiple trajectories OB2-1 to OB2-M are arranged at substantially constant intervals in the X direction. In this case, the interval between the multiple trajectories OB2-1 to OB2-M arranged may be related to the spot diameter Di of the spot areas 201i.

The irradiation with the laser beams 200i may be performed in one direction while tracing the trajectories OB2-1 to OB2-M in this order. FIGS. 23A to 23C illustrate a case where the irradiation with the laser beams 200i is performed along each trajectory OB2 from the +Y side to the −Y side, although the irradiation with the laser beams 200i may be performed along each trajectory OB2 from the −Y-side to the +Y side.

As illustrated in FIGS. 23A to 23C, the start points of a first multi-segment irradiation pattern, a second multi-segment irradiation pattern, and a third multi-segment irradiation pattern are shifted from one another at a distance away with the pre-segmentation pitch. The pre-segmentation pitch may be substantially equal to or slightly different from a spot diameter Di of the spot areas 201i for one irradiation, for example.

As illustrated in FIG. 23A, the first multi-segment irradiation pattern is formed of the spot areas 201i arranged along each trajectory OB2 at a pitch equal to three times the pre-segmentation pitch. As illustrated in FIG. 23B, the second multi-segment irradiation pattern is formed of the spot areas 201i arranged along each trajectory OB2 at a pitch equal to three times the pre-segmentation pitch. As illustrated in FIG. 23C, the third multi-segment irradiation pattern is formed of the spot areas 201i arranged along each trajectory OB2 at a pitch equal to three times the pre-segmentation pitch.

In the above way, each multi-segment irradiation can also form temporally adjacent spot areas 201i so as to be arranged at a sufficiently long spatial distance away. This can perform the irradiation steps using the laser beams 200i at a short time interval (or at a high irradiation frequency) with the thermal interference between the temporally adjacent spot areas 201i suppressed.

### Second Modification of Second Embodiment

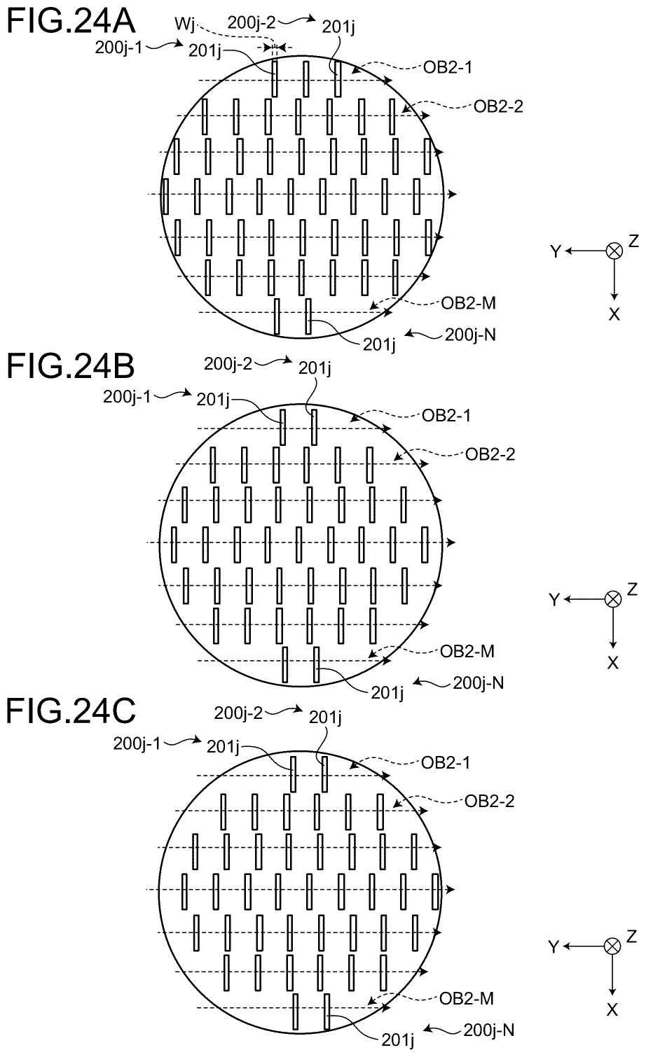

In a second modification of the foregoing second embodiment, K-time multi-segment irradiations may also be performed with linear spot areas 201j arranged along multiple linear trajectories OB2, as illustrated in FIGS. 24A to 24C. FIGS. 24A to 24C is an X-Y planar view illustrating multi-segment irradiation patterns according to the second modification of the second embodiment.

In a case of K=3, for example, three multi-segment irradiation patterns may be formed, as illustrated in FIGS. 24A to 24C. FIG. 24A illustrates an example of a first multi-segment irradiation pattern; FIG. 24B illustrates an example of a second multi-segment irradiation pattern; and FIG. 24C illustrates an example of a third multi-segment irradiation pattern. FIGS. 24A to 24C illustrate an example case where spot areas 201j each have a linear shape. In this case, a size of the multi-segment irradiation patterns having the line shape as illustrated in FIG. 24A to 24C is an example; as an alternative example, a length of the line shape in the longitudinal direction may be substantially the same as the longest diameter of the spot diameter Di illustrated in FIG. 23A to 23B, however not limited thereto.

As illustrated in FIGS. 24A to 24C, multiple trajectories OB2-1 to OB2-M are used for the K-time multi-segment irradiations. Here, M is any integer of 2 or more. The multiple trajectories OB2-1 to OB2-M extend substantially parallel to one another while arranged at substantially constant intervals in a direction perpendicular to the extending direction. In the case of FIGS. 24A to 24C, each of the trajectories OB2-1 to OB2-M extends in the Y direction. The multiple trajectories OB2-1 to OB2-M are arranged at substantially constant intervals in the X direction. Each spot area 201j extends in the X direction. In this case, the interval between the multiple trajectories OB2-1 to OB2-M arranged may be correspond to the length in the Y direction of the spot areas 201j.

At this time, the irradiation pitch when the laser beam is irradiated to trajectory OB2-1 to OB2-M over the entire surface of the substrate at a single time shall be referred to as a “pre-segmentation pitch”. The irradiation with the laser beams 200j may be performed in one direction while tracing the trajectories OB2-1 to OB2-M in this order. FIGS. 24A to 24C illustrate a case where the irradiation with the laser beams 200j is performed along each trajectory OB2 from the +Y side to the −Y side, although the irradiation with the laser beams 200j may be performed along each trajectory OB2 from the −Y side to the +Y side.

As illustrated in FIGS. 24A to 24C, the start points of a first multi-segment irradiation pattern, a second multi-segment irradiation pattern, and a third multi-segment irradiation pattern are shifted from one another at a distance away with the pre-segmentation pitch. The pre-segmentation pitch may be substantially equal to or slightly different from a spot width Wj in the Y direction of the spot areas 201j for one irradiation.

As illustrated in FIG. 24A, the first multi-segment irradiation pattern is formed of the spot areas 201j arranged along each trajectory OB2 at a pitch equal to three times the pre-segmentation pitch. As illustrated in FIG. 24B, the second multi-segment irradiation pattern is formed of the spot areas 201j arranged along each trajectory OB2 at a pitch equal to three times the pre-segmentation pitch. As illustrated in FIG. 24C, the third multi-segment irradiation pattern is formed of the spot areas 201j arranged along each trajectory OB2 at a pitch equal to three times the pre-segmentation pitch.

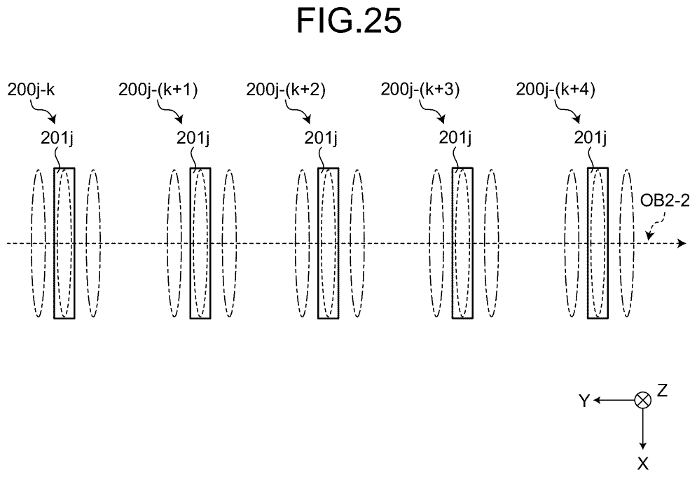

FIG. 25 illustrates the effect of this embodiment of irradiation using multi-segment irradiation pattern in a case of K=2. Consider an irradiation pattern, for example, as illustrated in FIG. 25, in which spot areas 201j, each of which linearly extends in the X direction, are arranged in the Y direction along a trajectory OB2-2 at a pitch corresponds to two times the pre-segmentation pitch.

In the first multi-segment irradiation pattern, when the spot area 201j is irradiated with a laser beam 200j-k for any k-th irradiation, compressive stress is generated in a region, as surrounded by the dotted lines in FIG. 25, that overlaps the spot area 201j on a principal surface 100b of a substrate 100 as viewed from the Z direction. Here, k is any integer. Tensile stress is generated in two regions, as surrounded by an alternate long and short dash line in FIG. 25, adjacent to both sides of the spot area 201j in the Y direction on the principal surface 100b of the substrate 100 as viewed from the Z direction.

Likewise, when the spot area 201j is irradiated with a laser beam 200j-(k+1) for the (k+1)-th irradiation, compressive stress is generated in a region, as surrounded by the dotted lines in FIG. 25, that overlaps the spot area 201j on the principal surface 100b of the substrate 100 as viewed from the Z direction. Tensile stress is generated in two regions, as surrounded by an alternate long and short dash line in FIG. 25, adjacent to both sides of the spot area 201j in the Y direction on the principal surface 100b of the substrate 100 as viewed from the Z direction.

Likewise, when the spot area 201j is irradiated with a laser beam 200j-(k+4) for the (k+4)-th irradiation, compressive stress is generated in a region, as surrounded by the dotted lines in FIG. 25, that overlaps the spot area 201j on the principal surface 100b of the substrate 100 as viewed from the Z direction. Tensile stress is generated in two regions, as surrounded by an alternate long and short dash line in FIG. 25, adjacent to both sides of the spot area 201j in the Y direction on the principal surface 100b of the substrate 100 as viewed from the Z direction.

In the second multi-segment irradiation pattern, multiple laser beams (not shown in FIG. 25) are irradiated between the spot areas 201j irradiated with laser beams 200j-k to 200j-(k+4) by the first multi-segment irradiation pattern. In the second multi-segment irradiation pattern, similar to the first multi-segment irradiation pattern, tensile stress is generated at the position illustrated by long and short dash line in FIG. 25. In other words, the positions of tensile stress generated by the first and second multi-segment irradiation pattern will be overlapped.

In the above way, this can perform the irradiation steps using the laser beams 200j at a short time interval (or at a high irradiation frequency) with the thermal interference between the temporally adjacent spot areas 201j suppressed.

### Third Modification of Second Embodiment

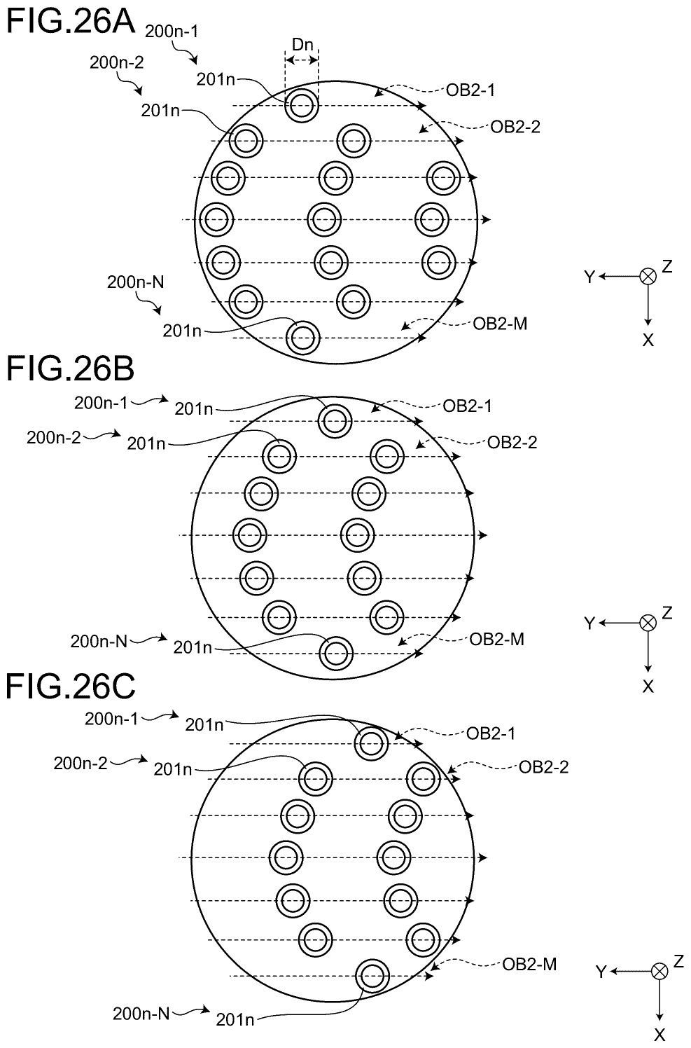

In a third modification of the foregoing second embodiment, K-time multi-segment irradiations may also be performed with ring-shaped spot areas 201n arranged along multiple linear trajectories OB2, as illustrated in FIGS. 26A to 26C. FIGS. 26A to 26C is an X-Y planar view illustrating multi-segment irradiation patterns according to the third modification of the second embodiment.

In a case of K=3, for example, three multi-segment irradiation patterns may be formed, as illustrated in FIGS. 26A to 26C. FIG. 26A illustrates an example of a first multi-segment irradiation pattern; FIG. 26B illustrates an example of a second multi-segment irradiation pattern; and FIG. 26C illustrates an example of a third multi-segment irradiation pattern. FIGS. 26A to 26C illustrate an example case where spot areas 201n each have a ring shape. In this case, a size of the multi-segment irradiation patterns having the ring shape as illustrated in FIG. 26A to 26C is an example; as an alternative example, an outer diameter of the ring shape may be substantially the same as or larger than that of the spot diameter illustrated in FIGS. 23A to 23C.

As illustrated in FIGS. 26A to 26C, multiple trajectories OB2-1 to OB2-M are used for the K-time multi-segment irradiations. Here, M is any integer of 2 or more. The multiple trajectories OB2-1 to OB2-M extend substantially parallel to one another while arranged at substantially constant intervals in a direction perpendicular to the extending direction. In the case of FIGS. 26A to 26C, each of the trajectories OB2-1 to OB2-M extends in the Y direction. The multiple trajectories OB2-1 to OB2-M are arranged at substantially constant intervals in the X direction. In this case, the interval between the multiple trajectories OB2-1 to OB2-M arranged may be correspond to the spot diameter Dn of the spot areas 201j.

The irradiation with the laser beams 200n may be performed in one direction while tracing the trajectories OB2-1 to OB2-M in this order. FIGS. 26A to 26C illustrate a case where the irradiation with the laser beams 200n is performed along each trajectory OB2 from the +Y side to the −Y side, although the irradiation with the laser beams 200n may be performed along each trajectory OB2 from the −Y side to the +Y side.

As illustrated in FIGS. 26A to 26C, the start points of the first multi-segment irradiation pattern, the second multi-segment irradiation pattern, and the third multi-segment irradiation pattern are shifted from one another at a distance away with the pre-segmentation pitch. The pre-segmentation pitch may be substantially equal to or slightly different from a spot diameter Dn of the spot areas 201n for each irradiation, for example.

As illustrated in FIG. 26A, the first multi-segment irradiation pattern is formed of the spot areas 201n arranged along each trajectory OB2 at a pitch equal to three times the pre-segmentation pitch. As illustrated in FIG. 24B, the second multi-segment irradiation pattern is formed of the spot areas 201n arranged along each trajectory OB2 at a pitch equal to three times the pre-segmentation pitch. As illustrated in FIG. 24C, the third multi-segment irradiation pattern is formed of the spot areas 201n arranged along each trajectory OB2 at a pitch equal to three times the pre-segmentation pitch.

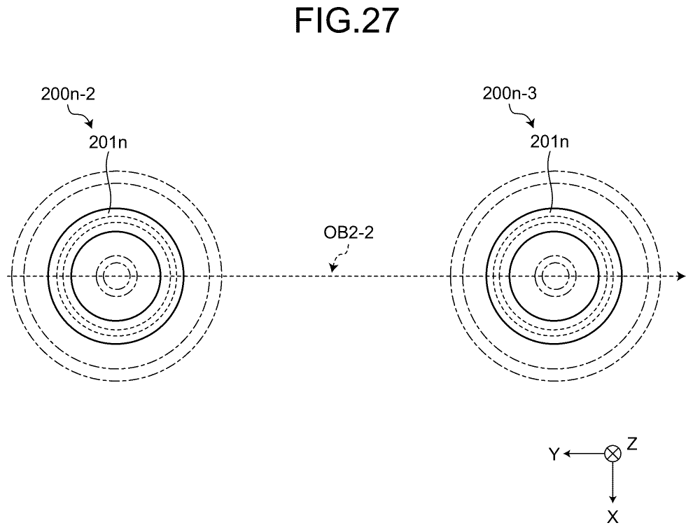

Consider an irradiation pattern, for example, as illustrated in FIG. 27, in which ring-shaped spot areas 201n are arranged in the Y direction along a trajectory OB2-2 at a pitch substantially equal to two times the spot diameter Dn of the spot areas 201n.

Similar to the explanation of FIG. 25, in the multi-segment irradiation pattern, when the spot area 201n is irradiated with a laser beam 200n-2 for the second irradiation, compressive stress is generated in a region, as surrounded by the dotted lines in FIG. 27, that overlaps the spot area 201n on a principal surface 100b of a substrate 100 as viewed from the Z direction. Tensile stress is generated in two regions, as surrounded by alternate long and short dash lines in FIG. 27, adjacent to the inner and outer sides of the spot area 201n in the X and Y directions on the principal surface 100b of the substrate 100 as viewed from the Z direction.

When the spot area 201n is irradiated with a laser beam 200n-3 for the third irradiation, compressive stress is generated in a region, as surrounded by the dotted lines in FIG. 27, that overlaps the spot area 201n on the principal surface 100b of the substrate 100 as viewed from the Z direction. Tensile stress is generated in two regions, as surrounded by alternate long and short dash lines in FIG. 27, adjacent to the inner and outer sides of the spot area 201n in the X and Y directions on the principal surface 100b of the substrate 100 as viewed from the Z direction.

In the second multi-segment irradiation pattern, multiple laser beams (not shown in FIG. 27) are irradiated between the spot areas 201j irradiated with laser beams 200n-2 and 200n-3 by the first multi-segment irradiation pattern. In the second multi-segment irradiation pattern, similar to the first multi-segment irradiation pattern, tensile stress is generated at the position illustrated by long and short dash line in FIG. 27. In other words, the positions of tensile stress generated by the first and second multi-segment irradiation pattern will be overlapped.

In the above way, this can perform the irradiation steps using the laser beams 200n at a short time interval (or at a high irradiation frequency) with the thermal interference between the temporally adjacent spot areas 201n suppressed.

The foregoing first and second embodiments and their modifications may be combined with one another.

Each of the first and second embodiments and their modifications has provided an example case where a semiconductor device 1 is manufactured with a technique for peeling one of bonded (contact) substrates; however, the method of peeling one of bonded (contact) substrates may be used for manufacturing silicon on insulator (SOI) substrates or other similar substrates.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
preparing a first substrate on which multiple projections distributed in a two-dimensional fashion are formed;
stacking a first film over the multiple projections on the first substrate;
stacking a second film on a second substrate;
bonding a principal surface of the first film which is disposed on an opposite side of the first substrate to a principal surface of the second film which is disposed on an opposite side of the second substrate; and
performing irradiation with a laser beam from the first substrate,
wherein
a diameter of a spot area formed by the laser beam is larger than an average pitch between the projections arranged on the principal surface of the first substrate.

2. The method of manufacturing a semiconductor device according to claim 1, wherein
the spot area formed by the laser beam overlaps two or more projections out of the multiple projections as viewed from a direction perpendicular to the principal surface of the first substrate.

3. The method of manufacturing a semiconductor device according to claim 2, wherein
the spot area formed by the laser beam includes the two or more projections inside as viewed from the direction perpendicular to the principal surface of the first substrate.

4. The method of manufacturing a semiconductor device according to claim 1, wherein
the multiple projections are distributed over the first substrate in a two-dimensional fashion and at identical pitches.

5. The method of manufacturing a semiconductor device according to claim 1, wherein
the multiple projections are formed by
processing a principal surface of the first substrate.

6. The method of manufacturing a semiconductor device according to claim 1, wherein
the multiple projections are formed by
depositing a third film on a principal surface of the first substrate and
processing the third film.

7. The method of manufacturing a semiconductor device according to claim 1, wherein
a thermal expansion coefficient of the first substrate is higher than a thermal expansion coefficient of the first film.

8. The method of manufacturing a semiconductor device according to claim 1, wherein
the irradiation is performed by irradiation along a spiral trajectory.

9. The method of manufacturing a semiconductor device according to claim 8, wherein
the spot area formed by the laser beam has a circular shape.

10. The method of manufacturing a semiconductor device according to claim 8, wherein
the spot area formed by the laser beam has a fan shape or a trapezoid shape.

11. The method of manufacturing a semiconductor device according to claim 1, further comprising
peeling the first substrate; and
planarizing a principal surface of the first substrate which has been peeled.

12. A method of manufacturing a semiconductor device, the method comprising:
stacking a first film on a first substrate and stacking a second film on a second substrate;
bonding a principal surface of the first film which is disposed on an opposite side of the first substrate to a principal surface of the second film which is disposed on an opposite side of the second substrate; and
performing irradiation of the first substrate with a laser beam, wherein
when each of K and N is an integer of 2 or more, the irradiation is performed by K-time multi-segment irradiations along a trajectory,
K-time multi-segment irradiations each includes a first step to N-th step of irradiating the first substrate with the laser beam and spot areas are formed for one irradiation, and
respective patterns formed by the K-time multi-segment irradiations are shifted at start points from each other at a first distance.

13. The method of manufacturing a semiconductor device according to claim 12, wherein
the trajectory has a spiral shape as viewed from a direction perpendicular to a principal surface of the first substrate.

14. The method of manufacturing a semiconductor device according to claim 12, wherein
the trajectory has a linear shape as viewed from a direction perpendicular to a principal surface of the first substrate.

15. The method of manufacturing a semiconductor device according to claim 13, wherein
each of the spot areas formed by the laser beam has a circular shape.

16. The method of manufacturing a semiconductor device according to claim 14, wherein
each of the spot areas formed by the laser beam has a circular shape.

17. The method of manufacturing a semiconductor device according to claim 14, wherein
each of the spot areas formed by the laser beam has a linear shape or a ring shape.

18. The method of manufacturing a semiconductor device according to claim 14, wherein
the first distance is substantially the same as a size of spot areas.

19. The method of manufacturing a semiconductor device according to claim 12, wherein
a thermal expansion coefficient of the first substrate is higher than a thermal expansion coefficient of the first film.

20. The method of manufacturing a semiconductor device according to claim 12, further comprising:
peeling the first substrate; and
planarizing a principal surface of the first substrate which has been peeled.
